(19) United States
(12) Patent Application Publication
(10) Pub. No.: US 2026/0136907 A1
(43) Pub. Date: May 14, 2026

(54) SEMICONDUCTOR STRUCTURE AND METHOD FOR MANUFACTURING THE SAME

(71) Applicant: Taiwan Semiconductor Manufacturing Company, Ltd., Hsinchu (TW)

(72) Inventors: Tzung-Yi WU, Zhubei City (TW); Chih-Hong HWANG, New Taipei City (TW); Cheng-Ying LIN, HsinChu City (TW); Chih-Ming CHIN, New Taipei City (TW); Ta-Chun LIN, Hsinchu (TW); Xiaodong WANG, Hsinchu City (TW); Jhon-Jhy LIAW, Zhudong Township (TW)

(21) Appl. No.: 18/941,460

(22) Filed: Nov. 8, 2024

(51) Int. Cl. H01L 23/48; H01L 29/06; H01L 29/417; H01L 29/423; H01L 29/66; H01L 29/775; H01L 29/786

(52) U.S. Cl. CPC H10W 20/20; H10D 30/6729; H10D 64/017; H10D 30/014; H10D 30/43; H10D 30/6735; H10D 30/6757; H10D 62/121

(57) ABSTRACT

A method for manufacturing a semiconductor structure includes forming a first fin and a second fin extending in a first direction. Each of the first and second fins includes first semiconductor layers and second semiconductor layers alternating stacked. The method further includes forming an isolation feature between the first and second fins in a second direction perpendicular to the first direction, forming a dummy gate structure over the first fin, the second fin, and the isolation feature, forming an interlayer dielectric layer on opposite sides of the dummy gate structure in the first direction, replacing the dummy gate structure and the first semiconductor layers with a gate structure, replacing the gate structure with a first dielectric structure, forming source/drain contacts on opposite sides of the first dielectric structure in the first direction, and forming a feed-through via under and in contact with the source/drain contacts.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a fragmentary diagrammatic top view of an integrated circuit (IC) chip, in portion or entirety, in accordance with some embodiments of the present disclosure.

FIG. 2A illustrates a top view (or a layout) of a semiconductor structure in the logic region or memory region of the IC chip, in accordance with some embodiments of the present disclosure.

FIG. 2B illustrates an X-Z cross-sectional view of the semiconductor structure along a line B-B′ of FIG. 2A, respectively, in accordance with some embodiments of the present disclosure.

FIG. 2C illustrates an X-Z cross-sectional view of the semiconductor structure along a line C-C′ of FIG. 2A, respectively, in accordance with some embodiments of the present disclosure.

FIG. 2D illustrates a Y-Z cross-sectional view of the semiconductor structure along a line D-D′ of FIG. 2A, respectively, in accordance with some embodiments of the present disclosure.

FIG. 2E illustrates a Y-Z cross-sectional view of the semiconductor structure along a line E-E′ of FIG. 2A, respectively, in accordance with some embodiments of the present disclosure.

FIG. 3 illustrates an X-Z cross-sectional view of the semiconductor structure along the line C-C′ of FIG. 2A, respectively, in accordance with some alternative embodiments of the present disclosure.

FIG. 4 is a perspective view of a workpiece at a fabrication stage for the semiconductor structure, in accordance with some embodiments of the present disclosure.

FIGS. 5A, 6A, 7A, 8A, 9A, 10A, 11A, 12A, and 13A illustrate top views (or layouts) of the workpiece at various fabrication stages for the semiconductor structure, in accordance with some embodiments of the present disclosure.

FIGS. 5B, 6B, 7B, 8B, 9B, 10B, 11B, 12B, and 13B illustrate X-Z cross-sectional views of the workpiece at various fabrication stages along lines B-B′ of FIGS. 5A to 13A, respectively, in accordance with some embodiments of the present disclosure.

FIGS. 5C, 6C, 7C, 8C, 9C, 10C, 11C, 12C, and 13C illustrate X-Z cross-sectional views of the workpiece at various fabrication stages along lines C-C′ of FIGS. 5A to 13A, respectively, in accordance with some embodiments of the present disclosure.

FIGS. 5D, 6D, 7D, 8D, 9D, 10D, 11D, 12D, and 13D illustrate Y-Z cross-sectional views of the workpiece at various fabrication stages along lines D-D′ of FIGS. 5A to 13A, respectively, in accordance with some embodiments of the present disclosure.

FIGS. 5E, 6E, 7E, 8E, 9E, 10E, 11E, 12E, and 13E illustrate Y-Z cross-sectional views of the workpiece at various fabrication stages along lines E-E′ of FIGS. 5A to 13A, respectively, in accordance with some embodiments of the present disclosure.

FIG. 14A illustrates a top view (or a layout) of a semiconductor structure in the logic region or memory region of the IC chip, in accordance with some alternative embodiments of the present disclosure.

FIG. 14B illustrates a Y-Z cross-sectional view of the semiconductor structure along a line E-E′ of FIG. 14A, respectively, in accordance with some alternative embodiments of the present disclosure.

FIG. 15A illustrates a top view (or a layout) of a semiconductor structure in the logic region or memory region of the IC chip, in accordance with some alternative embodiments of the present disclosure.

FIG. 15B illustrates an X-Z cross-sectional view of the semiconductor structure along a line B-B′ of FIG. 15A, respectively, in accordance with some alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor structures, and more particularly to semiconductor structures with field-effect transistors (FETs), such as three-dimensional gate-all-around (GAA) transistors, in memory (e.g., SRAM) and/or standard logic cells of an integrated circuit (IC) structure. Generally, a GAA transistor may include a plurality of vertically stacked sheets (e.g., nanosheets), wires (e.g., nanowires), or rods (e.g., nanorods) in a channel region of the transistor, thereby allowing better gate control, lowered leakage current, and improved scaling capability for various IC applications. While existing technologies for fabricating GAA transistors have been generally adequate for their intended applications, they have not been entirely satisfactory in all aspects.

The gate-all-around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and structures including a feed-through via structure that provides an electrical connection between a back-side metal conductor and a front-side metal line. The details of the structure and manufacturing methods of the present disclosure are described below in conjunction with the accompanying drawings, which illustrate the process of making GAA transistors, according to some embodiments.

The various aspects of the present disclosure will now be described in more detail with reference to the figures. For avoidance of doubts, an X-direction, a Y-direction, and a Z-direction in the figures are perpendicular to one another and are used consistently. Throughout the present disclosure, like reference numerals denote like features unless otherwise indicated.

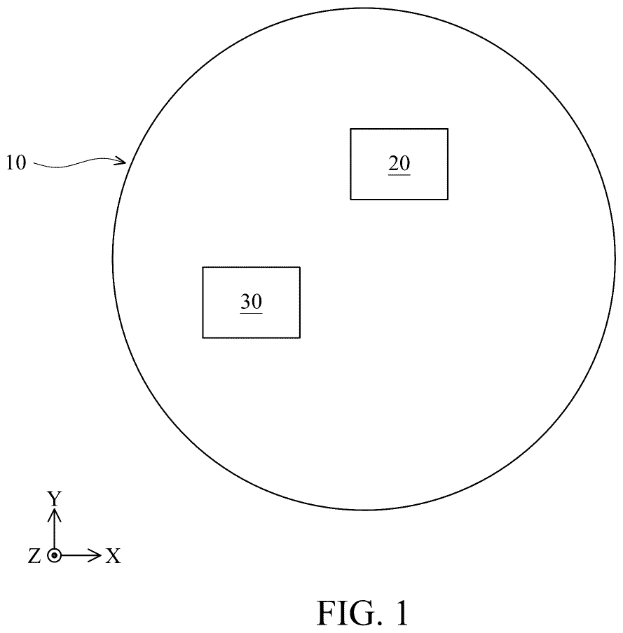

FIG. 1 is a fragmentary diagrammatic top view of an integrated circuit (IC) chip 10, in portion or entirety, in accordance with some embodiments of the present disclosure. The IC chip 10 may include various passive microelectronic devices and active microelectronic devices, such as resistors, capacitors, inductors, diodes, p-type field effect transistors (PFETs), n-type field effect transistors (NFETs), metal-oxide semiconductor field effect transistors (MOSFETs), CMOS transistors, bipolar junction transistors (BJTs), laterally diffused MOS (LDMOS) transistors, high voltage transistors, high frequency transistors, other suitable components, or combinations thereof.

The various microelectronic devices can be configured to provide the IC chip 10 with functionally distinct regions, such as a core region (also referred to as a logic region), a memory region (e.g., a static random access memory (SRAM) region), an analog region, a peripheral region (also referred to as an input/output (I/O) region), a dummy region, and/or other suitable region. In some embodiments, the IC chip 10 includes a memory region 20 and a logic region 30.

The memory region 20 can include an array of memory cells, each of which includes transistors and interconnection structures (also referred to as routing structures) that combine to provide a storage device and/or a storage function, such as a flip flop, a latch, other suitable semiconductor devices, or a combination thereof. In some embodiments, the memory region 20 is configured with static random-access memory (SRAM) cells, dynamic random-access memory (DRAM) cells, non-volatile random-access memory (NVRAM) cells, flash memory cells, other suitable memory cells, or a combination thereof.

The logic region 30 can include an array of circuit cells having various logic cells or standard (STD) cells. The logic cells or STD cells may include transistors and interconnection structures that combine to provide a logic device and/or a logic function, such as an inverter, an AND, a NAND, an OR, an NOR, a NOT, an XOR, an XNOR, other suitable logic devices, or combinations thereof.

FIG. 1 has been simplified for the sake of clarity to better understand the inventive concepts of the present disclosure. Additional features can be added to IC chip 10, and some of the features described herein can be replaced, modified, or eliminated in other embodiments of the IC chip 10. In some embodiments, feed-through via structures can be formed or placed in the memory region 20 and the logic region 30. The feed-through via structures may be also referred to as feed-through cell. The feed-through via structures are used for electrical connection between back-side metal lines and front-side metal lines.

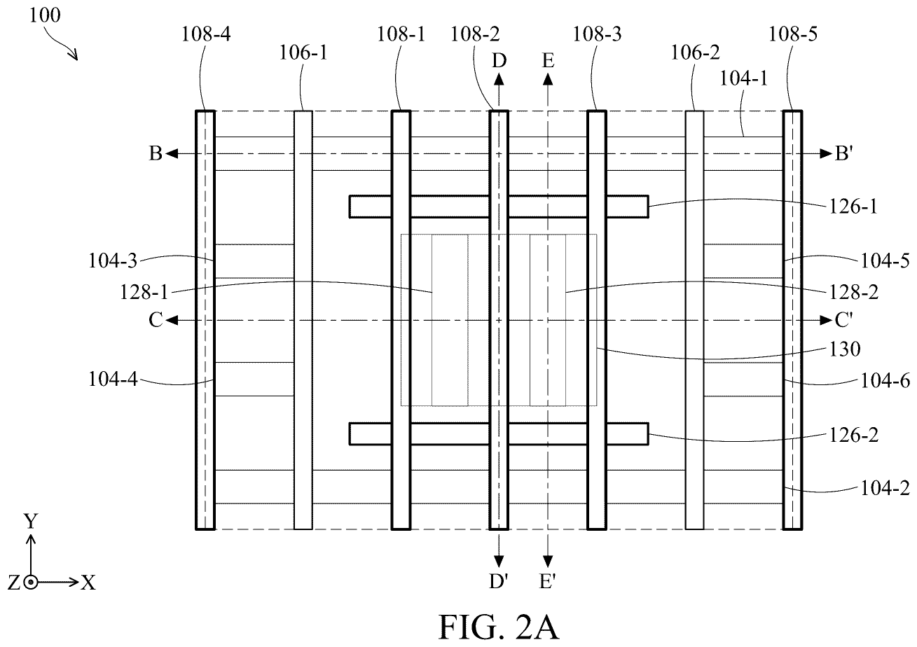

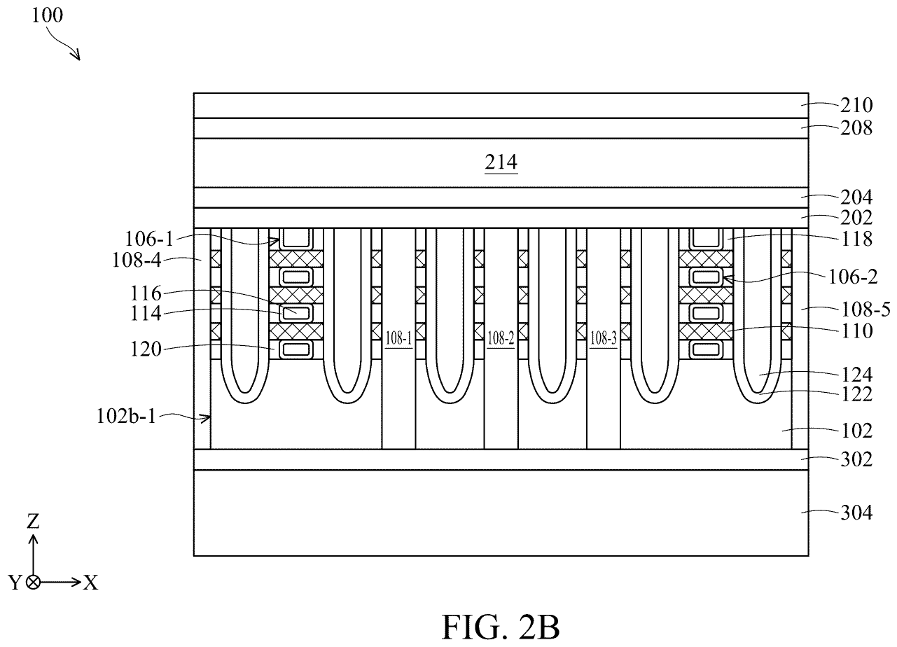

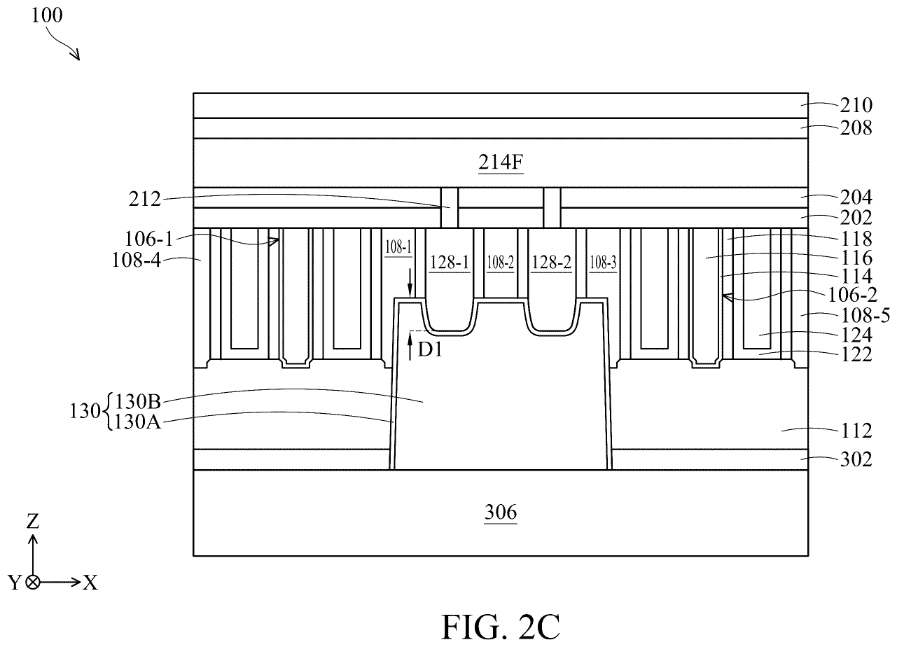

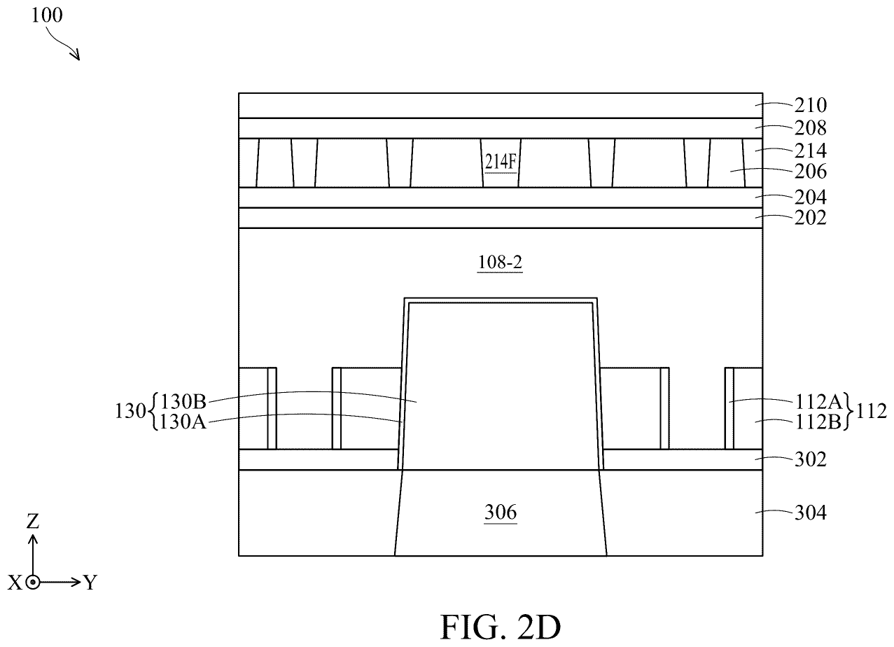

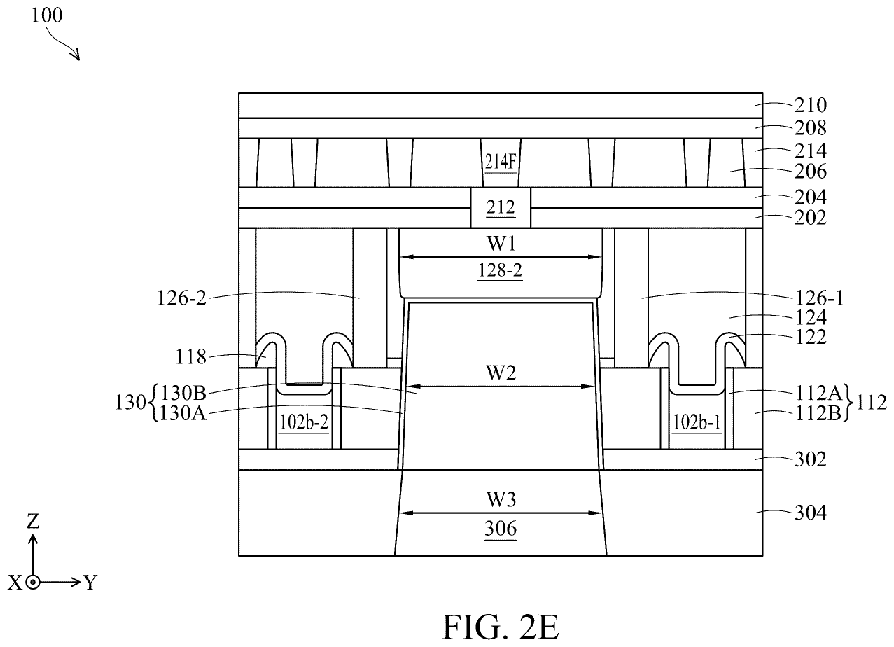

FIG. 2A illustrates a top view (or a layout) of a semiconductor structure 100 in the logic region 30 or memory region 20 of the IC chip 10, in accordance with some embodiments of the present disclosure. FIG. 2B illustrates an X-Z cross-sectional view of the semiconductor structure 100 along a line B-B′ of FIG. 2A, respectively, in accordance with some embodiments of the present disclosure. FIG. 2C illustrates an X-Z cross-sectional view of the semiconductor structure 100 along a line C-C′ of FIG. 2A, respectively, in accordance with some embodiments of the present disclosure. FIG. 2D illustrates a Y-Z cross-sectional view of the semiconductor structure 100 along a line D-D′ of FIG. 2A, respectively, in accordance with some embodiments of the present disclosure. FIG. 2E illustrates a Y-Z cross-sectional view of the semiconductor structure 100 along a line E-E′ of FIG. 2A, respectively, in accordance with some embodiments of the present disclosure.

As shown in FIGS. 2A to 2E, the semiconductor structure 100 shows a feed-through structure or a feed-through cell including a feed-through via 130 and source/drain contacts 128-1 and 128-2. The semiconductor structure 100 includes active areas 104-1 to 104-6 (may be collectively referred to as active areas 104) that extend lengthwise in the X-direction. Each of active areas 104 includes channel regions, source regions, and drain regions (where source regions and drain regions are collectively referred to as source/drain regions herein) of transistors of the semiconductor structure 100.

In some embodiments, the active areas 104-1 to 104-6 are separated from each other in the Y-direction. More specifically, as shown in FIG. 2A, the active areas 104-1 and 104-2 are arranged in the Y-direction and the active areas 104-3 to 104-6 are between the active areas 104-1 and 104-2 in the Y-direction. In some aspects, the active areas 104-1, 104-3, 104-4, and 104-2 are arranged in the Y-direction and the active areas 104-1, 104-5, 104-6, and 104-2 are arranged in the Y-direction. Furthermore, the active area 104-3 is separated from the active area 104-5 in the X-direction and the active area 104-3 is separated from the active area 104-5 in the X-direction, as shown in FIG. 2A. Therefore, the active areas 104-1 to 104-6 surround an area for disposing the feed-through structure/cell, as shown in FIGS. 2A to 2E.

Referring to FIGS. 2B and 2E, the semiconductor structure 100 includes a substrate 102, over which the various features are formed. In some embodiments, each of the active areas 104-1 to 104-6 has a base fin. For examples, as shown in FIGS. 2B and 2E, the active area 104-1 has a base fin 102b-1 and the active area 104-1 has a base fin 102b-2. The base fins 102b-1 and 102b-2 are protruded from a substrate 102. The substrate 102 may contains a semiconductor material, such as bulk silicon (Si). In some other embodiments, the substrate 102 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). Alternatively, the substrate 102 may be a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates may be fabricated using separation by implantation of oxygen (SIMOX), wafer bonding, and/or other suitable methods.

The semiconductor structure 100 further includes an isolation feature (or isolation structure) 112 over the substrate 102 and isolating the adjacent active areas 104. In some embodiments, the isolation feature 112 is formed between the base fins 102b-1 and 102b-2 of the substrate 102 in the Y-direction, as shown in FIG. 2E. The isolation feature 112 may include different structures, such as shallow trench isolation (STI) structure and/or deep trench isolation (DTI) structures. In some embodiments, the isolation feature 112 may also be referred to as shallow trench isolation (STI) feature.

In some embodiments, the isolation feature 112 may have a multi-layer structure such as one or more liner layer over the substrate 102 and a filling layer over the liner layer. More specifically, as shown in FIGS. 2D and 2E, the isolation feature 112 is formed form a liner layer 112A and a dielectric material 112B (i.e., the filling layer). In some embodiments, the material for the liner layer 112A includes silicon oxide. The dielectric material 112B may include silicon oxide, silicon nitride, silicon oxynitride, other suitable isolation material (for example, including silicon, oxygen, nitrogen, carbon, or other suitable isolation constituent), or a combination thereof.

As shown in FIG. 2B, each of the active areas 104-1 to 104-6 has nanostructures 110 in the channel regions of the active areas 104-1 to 104-6. The nanostructures 110 of the active areas 104-1 to 104-6 are disposed over the base fins (e.g., the base fins 102b-1 and 102b-2), as shown in FIG. 2B. As shown in FIG. 2B, the nanostructures 110 are suspended over the base fin 102b-1 of the substrate 310.

In some embodiments, three nanostructures 110 are vertically stacked (or vertically arranged) from each other in the Z-direction for one transistor. However, there may be another appropriate number of nanostructures in one transistor. For example, there may be from 2 to 10 nanostructures 110. The nanostructures 110 further extend lengthwise in the X-direction (FIG. 2B) and widthwise in the Y-direction (not shown). As shown in FIG. 2B, three nanostructures 110 are spaced apart from each other in the Z-direction.

The nanostructures 110 may include a semiconductor material, such as silicon, germanium, silicon carbide, silicon phosphide, gallium arsenide, gallium phosphide, indium phosphide, indium arsenide, and/or indium antimonide, silicon germanium (SiGe), SiPC, GaAsP, AlInAs, AlGaAs, GaInAs, GaInP, and/or GaInAsP. In some embodiments, the nanostructures 110 include silicon for N-type transistors. In other embodiments, the nanostructures 110 include silicon germanium for P-type transistors. In some embodiments, the nanostructures 110 are all made of silicon, and the type of the transistors depend on the work function metal layer wrapping around the nanostructures 110. In some embodiments, the nanostructures 110 are epitaxially grown using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized.

The semiconductor structure 100 further includes gate structures and dielectric structures, such as gate structures 106-1 and 106-2 (may be collectively referred to as gate structures 106) and dielectric structures 108-1 to 108-5 (may be collectively referred to as dielectric structures 108). The gate structures 106-1 to 106-2 and dielectric structures 108-1 to 108-5 are disposed over the substrate 102 and the isolation feature 112. Furthermore, the dielectric structures 108-1 to 108-5 pass through the substrate 102, as shown in FIG. 2B.

The gate structures 106-1 to 106-2 and dielectric structures 108-1 to 108-5 extend substantially parallel to one another, extend lengthwise in the Y-direction perpendicular to the X-direction, and are separated from each other in the X-direction, as shown in FIGS. 2A to 2E. As shown in FIGS. 2A to 2E, the dielectric structures 108-1 to 108-3 are disposed over the active areas 104-1 and 104-2, the gate structures 106-1 and the dielectric structure 108-4 are disposed over the active areas 104-1, 104-3, 104-4, and 104-2, and the gate structures 106-2 and the dielectric structure 108-5 are disposed over the active areas 104-1, 104-5, 104-6, and 104-2.

The dielectric gate structures 108 and the gate structures 106 are arranged in the X-direction. Furthermore, as shown in FIGS. 2A to 2E, the dielectric structures 108-1 and 108-3 are disposed on opposite sides of the dielectric structure 108-2 in the X-direction, the gate structures 106-1 and 106-2 are disposed on opposite sides of the dielectric structures 108-1 to 108-3 in the X-direction, and the dielectric structures 108-4 and 108-5 are disposed on opposite sides of the dielectric structures 108-1 to 108-3 and the gate structures 106-1 and 106-2 in the X-direction. In some aspects, the dielectric structures 108-1 to 108-3 are disposed between the gate structures 106-1 and 106-2 in the X-direction, the gate structure 106-1 is disposed between the dielectric structures 108-4 and 108-1 in the X-direction, and the gate structure 106-2 is disposed between the dielectric structures 108-3 and 108-5 in the X-direction

The gate structures 106-1 and 106-2 are disposed over the channel regions of the respective active areas 104-1 to 104-6 (i.e., the (vertically stacked) nanostructures). In some embodiments, the gate structures 106-1 and 106-2 wrap and/or surround suspended, vertically stacked nanostructures 110 in the channel regions of the active areas 104-1 to 104-6, respectively (as shown in FIG. 2B). More specifically, as shown in FIGS. 2B, each of the gate structures 106-1 and 106-2 wrap around the nanostructures 110 in the channel regions of the active areas 104-1 to 104-6. For example, the gate structure 106-1 wraps around the nanostructures 110 in the active area 104-1 and the gate structure 106-2 wraps around the nanostructures 110 in the active area 104-1.

Each of the gate structures 106-1 and 106-2 has a gate dielectric layer 114 and a gate electrode layer 116. The gate dielectric layers 114 wrap around each of the nanostructures 110 and the gate electrode layers 116 wrap around the nanostructures 110 and the gate dielectric layer 114. In some embodiments, each of the gate structures 106 further includes an interfacial layer (such as having silicon dioxide, silicon oxynitride, or other suitable materials) between the gate dielectric layer 114 and the nanostructures 110. The gate dielectric layers 114 may include oxide with nitrogen doped dielectric material (initial layer) combined with metal content high-K dielectric material (K value (dielectric constant)>13). For example, gate dielectric layers 114 may include hafnium oxide (HfO₂), which has a dielectric constant in a range from about 18 to about 40. Alternatively, the gate dielectric layers 114 may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. The gate dielectric layers 114 may be formed by chemical oxidation, thermal oxidation, ALD, CVD, and/or other suitable methods.

The gate electrode layer 116 is formed to wrap around the gate dielectric layer 114 and the center portions of the nanostructures 110, as shown in FIG. 2B. In some embodiments, the gate electrode layer 116 may include an N-type work function metal layer or a P-type work function metal layer. The N-type work function metal layer and the P-type work function metal layer may be selected from a group consisting of TiN, TaN, TiAl, TiAlN, TaAl, TaAlN, TaAlC, TaCN, WNC, Co, Ni, Pt, W, or a combination thereof, in accordance with some embodiments. The material of the N-type work function metal layer and the P-type work function metal layer may be the same. In some embodiments, the material of the N-type work function metal layer and the P-type work function metal layer are different.

In some embodiments, the N-type work function metal layer is a material such as Ti, Al, Ag, Mn, Zr, TiAl, TiAlC, TaC, TaCN, TaSiN, TaAl, TaAlC, TiAlN, other suitable N-type work function materials, or combinations thereof. For example, the N-type work function metal layer may be deposited utilizing ALD, CVD, or the like. However, any suitable materials and processes may be utilized to form the N-type work function metal layer.

In some embodiments, the P-type work function metal layer is a material such as TiN, TaN, Ru, Mo, Al, WN, ZrSi₂, MoSi₂, TaSi₂, NiSi₂, other metal oxides, metal nitrides, metal silicates, transition metal-oxides, transition metal-nitrides, transition metal-silicates, oxynitrides of metals, metal aluminates, zirconium silicate, zirconium aluminate, other suitable P-type work function materials, combinations of these, or the like. Additionally, the P-type work function metal layer may be deposited using a deposition process such as ALD, CVD, or the like, although any suitable deposition process may be used.

In some embodiments, the gate electrode layer 116 may include a single layer or alternatively a multi-layer structure. In some embodiments, the gate electrode layer 116 may further include a capping layer, a barrier layer, and a fill material (not shown). The capping layer may be formed adjacent to the gate dielectric layers 114 and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The metallic material may be deposited using a deposition process such as ALD, CVD, or the like, although any suitable deposition process may be used. The barrier layer may be formed adjacent the capping layer, and may be formed of a material different from the capping layer. For example, the barrier layer may be formed of a material such as one or more layers of a metallic material such as TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be deposited using a deposition process such as atomic layer deposition, chemical vapor deposition, or the like, although any suitable deposition process may be used.

As discussed above, the dielectric structures 108 extend lengthwise in the Y-direction (e.g., parallel to the gate structures 106), as show in FIG. 2A. In some embodiments, the dielectric structures 108 may be single dielectric layer or multiple layers and selected from a group consisting of SiO₂, Si₃N₄, SiOC, SiON, SiOCN, carbon content oxide, nitrogen content oxide, carbon and nitrogen content oxide, metal oxide dielectric, Hf oxide (HfO₂), Ta oxide (Ta₂O₅), Ti oxide (TiO₂), Zr oxide (ZrO₂), Al oxide (Al₂O₃), Y oxide (Y₂O₃), multiple metal content oxide, or combinations thereof.

The semiconductor structure 100 further include gate spacers 118 on sidewalls of the gate structures 106 and the dielectric structures 108, and over the nanostructures 110, as shown in FIGS. 2B and 2C. The gate spacers 118 are over the nanostructures 110 and on top sidewalls of the gate structures 106 and the dielectric structures 108, and thus are also referred to as gate top spacers or top spacers. Furthermore, the gate spacers 118 are over and in contact with the isolation feature 112, as shown in FIG. 2C.

The gate spacers 118 may include multiple dielectric materials and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, air gap, or a combination thereof. In some embodiments, the gate spacers 118 may include a single layer or a multi-layer structure.

As shown in FIG. 2B, the semiconductor structure 100 further includes inner spacers 120 on the sidewalls of the gate structures 106 and the dielectric structures 108, and below the topmost nanostructures 110. The inner spacers 120 are also vertically between adjacent nanostructures 110 and between bottommost nanostructures 100 and the substrate 102. The inner spacers 120 may include a dielectric material having higher K value (dielectric constant) than the gate spacers 118 and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), air gap, or a combination thereof.

In some embodiments, the thickness of the gate spacers 118 in the X-direction and the thickness of the inner spacers 120 in the X-direction are the same. In other embodiments, the thickness of the gate spacers 118 in the X-direction is less than the thickness of the inner spacers 120 in the X-direction.

The semiconductor structure 100 further includes a contact etch stop layer (CESL) 122 and an interlayer dielectric (ILD) layer 124 over the CESL 122. More specifically, the CESL 148 is conformally on the sidewalls of the gate spacers 118, the inner spacers 120, the nanostructures 110, the isolation feature 112, over the substrate 102 and the isolation feature 112, as shown in FIGS. 2B, 2C, and 2E. The ILD layer 124 is then formed over the CESL 122 to fill remaining spaces between (or inside) the CESL 122. As shown in FIGS. 2B and 2C, the CESL 122 and the ILD layer 124 are also on opposite sides of the gate structures 106 and the dielectric structures 108 in the X-direction. In other words, the CESL 122 and the ILD layer 124 are also between the dielectric structures 108 and between one of the gate structures 106 and one of the dielectric structures 108, as shown in FIGS. 2B and 2C.

It should be noted that the sidewalls of the nanostructures 110 are in contact with the CESL 148 in the X-direction rather than source/drain features. As such, the transistors formed in the active areas 104-1 to 104-6 are non-functional. Therefore, the transistors formed in the active areas 104-1 to 104-6 may also be referred to as non-functional transistors or dummy transistors.

The CESL 122 includes a material that is different than ILD layer 124. The CESL 122 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material(s); and may be formed by CVD, PVD, ALD, or other suitable methods. The ILD layer 124 may comprise tetraethylorthosilicate (TEOS) formed oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. The ILD layer 124 may be formed by PECVD (plasma enhanced CVD), FCVD (flowable CVD), or other suitable methods.

The semiconductor structure 100 further includes dielectric structures 126-1 and 126-2 (may be collectively referred to as dielectric structures 126) over the isolation feature 112, as shown in FIGS. 2A and 2E. In some embodiments, the dielectric structures 126 extend lengthwise in the X-direction. The dielectric structures 126 are on opposite sides of the area for disposing the feed-through structure/cell in the Y-direction. It should be noted that the dielectric structures 126 are non-continuous features. More specifically, as shown in FIGS. 2A to 2E, each of the dielectric structures 126-1 and 126-2 are divided into multiple segments by the dielectric structures 108-1 to 108-3. In some aspects each of the dielectric structures 126-1 and 126-2 is between the dielectric structures 108-1 to 108-3, as shown in FIGS. 2A to 2E. The material of the dielectric structures 126 is selected from a group consisting of Si₃N₄, SION, SiOC, SiOCN, metal content dielectric, high K material (K>=9), or a combination thereof.

The semiconductor structure 100 further includes source/drain contacts 128-1 and 128-2 (may be collectively referred to as source/drain contacts 128) in the ILD layer 124. The source/drain contacts 128-1 and 128-2 extend lengthwise in the Y-direction. As shown in FIGS. 2A and 2E, in the top view, the source/drain contacts 128-1 and 128-2 are on opposite sides of the dielectric structure 108-2 in the X-direction. In some aspects, the source/drain contact 128-1 is between the dielectric structures 108-1 and 108-2 in the X-direction, and the source/drain contact 128-2 is between the dielectric structures 108-2 and 108-3 in the X-direction, as shown in FIGS. 2A and 2E. In some embodiments, the source/drain contacts 128 are between the dielectric structures 126-1 and 126-2 in the Y-direction, as shown in FIGS. 2A and 2E.

In some embodiments, the source/drain contacts 128 are self-aligned source/drain contacts. This means that the source/drain contacts 128 are formed by using the gate spacers 118 as masks. Therefore, the source/drain contacts 128 are in direct contact with the gate spacers 118, as shown in FIG. 2C. In some embodiments, the gate spacers 118 are trimmed due to the gate spacers 118 serving as the mask for forming the source/drain contacts 128. Therefore, the thickness of the gate spacers 118 in the X-direction is less than the thickness of the inner spacers 120 in the X-direction, as discussed above. In some embodiments, top surfaces of the source/drain contacts 128 are substantially level with top surfaces of the gate structures 106, the dielectric structures 108, and gate spacers 118 when the source/drain contacts 128 are self-aligned source/drain contacts.

In some embodiments, the source/drain contacts 128 are non-self-aligned source/drain contacts. This means that the source/drain contacts 128 are not formed by using the gate spacers 118 as masks. In these embodiments, the source/drain contacts 128 may be separated from the gate spacers 118 by a dielectric layer (e.g., an interlayer dielectric (ILD) layer 124). As such, the contact-to-gate parasitic capacitance is reduced. Furthermore, in these embodiments, the thickness of the gate spacers 118 in the X-direction and the thickness of the inner spacers 120 in the X-direction are the same. In some embodiments, the top surfaces of the source/drain contacts 128 are higher than the top surfaces of the of the gate structures 306, the dielectric structures 108, and gate spacers 118 when the source/drain contacts 128 are non-self-aligned source/drain contacts.

Originally, the source/drain contacts are conductive features over the source/drain features in the source/drain region of the active areas formed at a source/drain contact process stage. However, the source/drain contacts 128-1 and 128-2 are used for feed-through structure/cell. More specifically, the source/drain contacts 128-1 and 128-2 are not over and electrically connected to the source/drain features. In some embodiments, the source/drain contacts 128-1 and 128-2 may also be referred to as dummy source/drain contacts.

The source/drain contacts 128 may each include a conductive material such as Al, Cu, W, Co, Ti, Ta, Ru, Rh, Ir, Pt, Mo, TiN, TiAl, TiAlN, TaN, TaC, combinations of these, or the like, although any suitable material may be deposited using a deposition process such as sputtering, CVD, electroplating, electroless plating, or the like. In some embodiments, the source/drain contacts 128 may each include single conductive material layer or multiple conductive layers.

The semiconductor structure 100 further includes a feed-through via 130 under and in contact with the source/drain contacts 128-1 and 128-2. In some embodiments, the feed-through via 130 is electrically connected to the source/drain contacts 128-1 and 128-2. As shown in FIGS. 2C to 2E, the feed-through via 130 is also under and in contact with the dielectric structures 108-1 to 108-3, as shown in FIGS. 2C and 2D. Furthermore, the feed-through via 130 passes through the isolation feature 112. In some embodiments, the feed-through via 130 is in contact with sidewalls of the dielectric structures 108-1 and 108-3 in the X-direction, as show in FIG. 2C. The feed-through via 130 further includes an adhesion layer 130A and a conductive layer 130B. The adhesion layer 130A includes Ti/TiN layer and the conductive layer 130B includes W.

It should be noted that a topmost surface of the feed-through via 130 is higher than bottom surfaces of the source/drain contacts 128-1 and 128-2, as shown in FIG. 2C. In other words, the feed-through via 130 is in contact with sidewalls of the source/drain contacts 128-1 and 128-2, as shown in FIG. 2C. Therefore, the contact area between the source/drain contacts 128 and the feed-through via 130 is increased to reduce the contact resistance between the source/drain contacts 128 and the feed-through via 130, thereby improving the performance of the semiconductor structure 100.

In some embodiments, a distance D1 between the topmost surface of the feed-through via and the bottom surfaces of the source/drain contacts 128-1 and 128-2 in the Z-direction (i.e., a dimension of an interface between the feed-through via and the sidewalls of the source/drain contacts 128-1 and 128-2 in the Z-direction) is in a range from about 15 nm to about 25 nm, as shown in FIG. 2C. If the distance D1 is too small (the distance D1 is less than about 15 nm), the contact resistance between the source/drain contacts 128 and the feed-through via 130 cannot be significantly reduced. If the distance D1 is too large (the distance D1 is greater than about 25 nm), the process window for forming such distance D1 is small and the process reliability is reduced.

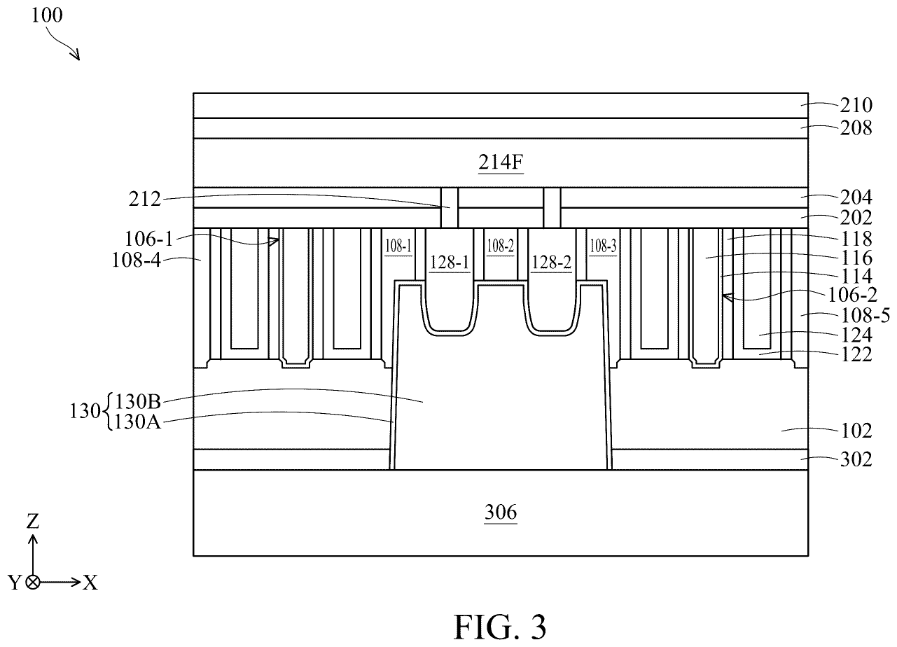

In some embodiments, the topmost surface of the feed-through via 130 is level with one third (⅓) of the dimension of sidewalls of the source/drain contacts 128-1 and 128-2 in the Z-direction, as shown in FIG. 2C. In other embodiments, the topmost surface of the feed-through via 130 is level with a half of the dimension of the sidewalls of the source/drain contacts 128-1 and 128-2 in the Z-direction, as shown in FIG. 3.

As shown in FIGS. 2A, sidewalls of the feed-through via 130 are aligned with the sidewalls of the source/drain contacts 128-1 and 128-2 in the X-direction. In other words, a width W1 of the source/drain contacts 128-1 and 128-2 in the Y-direction and a width W2 of the feed-through via 130 in the Y-direction are the same, as shown in FIG. 2E. Furthermore, the feed-through via 130 is between the dielectric structures 126-1 and 126-2 in the Y-direction, as shown in FIGS. 2A and 2E. As shown in FIGS. 2A and 2E, the feed-through via 130 is separated from the dielectric structures 126-1 and 126-2 in the Y-direction. In some embodiments, a distance between the feed-through via 130 and the dielectric structures 126-1 and 126-2 in the Y-direction is greater than or equal to 5.5 nm. The dielectric structures 126-1 and 126-2 are used for enhancing the isolation of the feed-through via 130 (specifically, the feed-through structure/cell) from other features in the Y-direction. If the distance between the feed-through via 130 and the dielectric structures 126-1 and 126-2 in the Y-direction is less than 5.5 nm, the isolation effect is reduced.

As shown in FIGS. 2A and 2C, the feed-through via 130 is between the gate structures 106-1 and 106-2 in the X-direction. In some embodiments, the sidewalls of the feed-through via 130 are separated from the gate structures 106-1 and 106-2 in the X-direction, as shown in FIGS. 2A and 2C. In some embodiments, a distance between the sidewalls of the feed-through via 130 and the gate structures 106-1 and 106-2 in the X-direction is in a range from about 20.2 nm to about 45 nm.

The semiconductor structure 100 further includes a front-side interconnection structure including a CESL 202, an ILD layer 204, an ILD layer 206, a CESL 208, an ILD layer 210, vias 212, metal conductors 214, and a metal conductor 214F. The CESL 202 is over the gate structures 106, the dielectric structures 108, and the source/drain contacts 128, the ILD layer 204 is over the CESL 202, the ILD layer 206 is over the ILD layer 204, the CESL 208 is over the ILD layer 206, and the ILD layer 210 is over the CESL 208. The CESLs 202 and 208 include a material similar to the material of the CESL 122 discussed above. The ILD layers 204, 206, and 210 include a material similar to the material of the ILD layer 124 discussed above.

The vias 212 are disposed in and pass through the CESL 202 and the ILD layer 204, as shown in FIGS. 2C and 2E. Furthermore, the vias 212 are over and in contact with the source/drain contacts 128, as shown in FIGS. 2C and 2E. The vias 212 are also electrically connected to the source/drain contacts 128. The metal conductors 214 and 214F are disposed in and pass through the ILD layer 206, as shown in FIGS. 2B to 2E. As shown in FIGS. 2B to 2E, the metal conductors 214 and 214F extend lengthwise in the X-direction and arranged in the Y-direction, as shown in FIGS. 2B to 2E. In some embodiments, the metal conductor 214F is over and in contact with the vias 212. The metal conductor 214F is also electrically connected to the vias 212. As shown in FIG. 2E, a width of the vias 212 in the Y-direction is greater than a width of the metal conductor 214F in the Y-direction to have lower contact resistance between the vias 212 and the metal conductor 214F, thereby improving the performance of the semiconductor structure 100. Furthermore, larger vias 212 have lower resistance. The vias 212 and the metal conductors 214 and 214F may also be referred to as front-side vias and front-side metal conductors, in accordance with some embodiments.

The semiconductor structure 100 further includes a dielectric layer 302 and a back-side interconnection structure including an ILD layer 304 and a metal conductor 306. The dielectric layer 302 is under the substrate 102 and the isolation feature 112, and the ILD layer 304 is under the dielectric layer 302. The ILD layer 304 includes a material similar to the material of the ILD layer 124 discussed above. As shown in FIG. 2D to 2E, the feed-through via 130 also passes through the dielectric layer 302. The metal conductor 306 is disposed in and pass through the ILD layer 304, as shown in FIGS. 2D to 2E. As shown in FIGS. 2B to 2E, the metal conductor 306 extends lengthwise in the X-direction, as shown in FIGS. 2B to 2E. In some embodiments, the metal conductor 306 is under and in contact with the feed-through via 130. The metal conductor 306 is also electrically connected to the feed-through via 130. As shown in FIG. 2E, a width W3 of the metal conductor 306 in the Y-direction and the width W2 of the feed-through via 130 in the Y-direction are the same to maximize the contact area between the metal conductor 306 and the feed-through via 130 to have lower contact resistance between the metal conductor 306 and the feed-through via 130, thereby improving the performance of the semiconductor structure 100. Furthermore, larger metal conductor 306 have lower resistance. The metal conductor 306 may also be referred to as back-side metal conductors, in accordance with some embodiments.

The dielectric layer 302 includes a dielectric material nitride, such as Si₃N₄, SiO₂, SiC, SiOC, SiON, SiCN, SiOCN, carbon doped oxide, nitrogen doped oxide, porous oxide, or combinations thereof. The materials of the vias 212, and the metal conductors 214, 214F, and 306 are selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or a combination thereof.

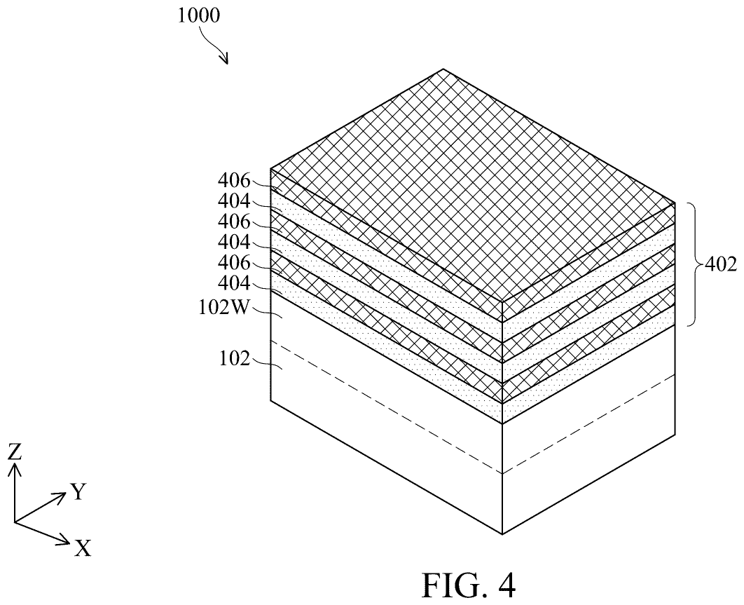

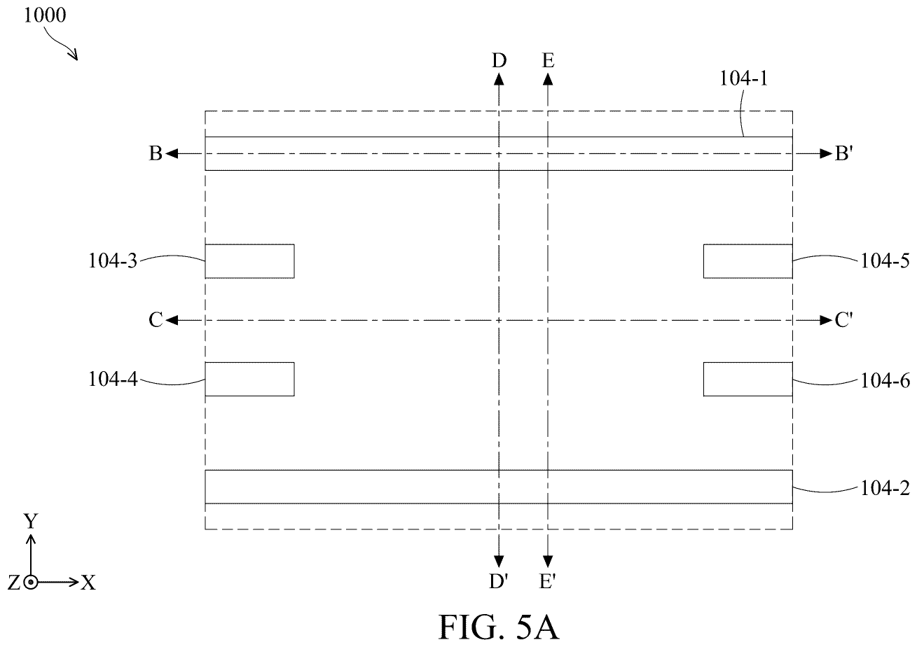

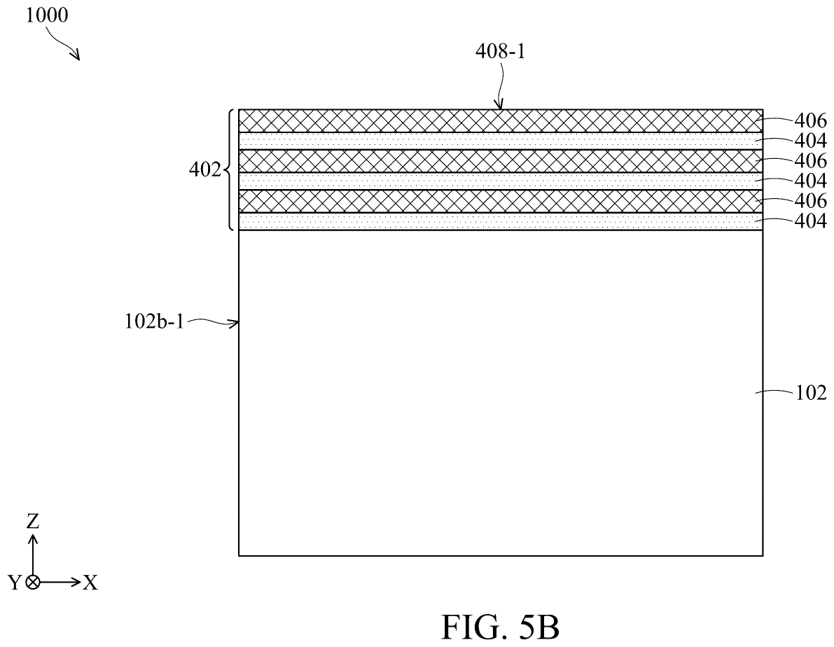

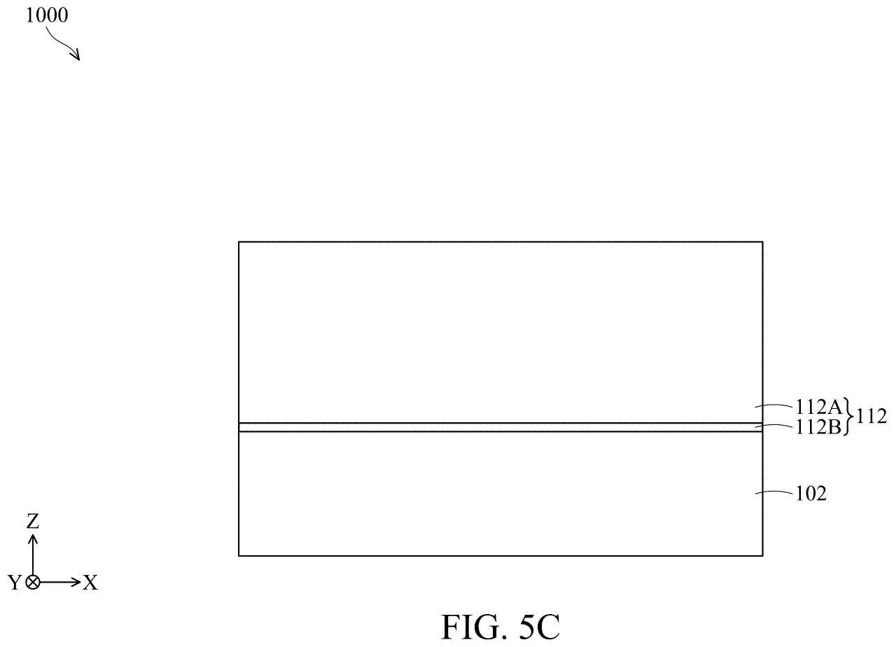

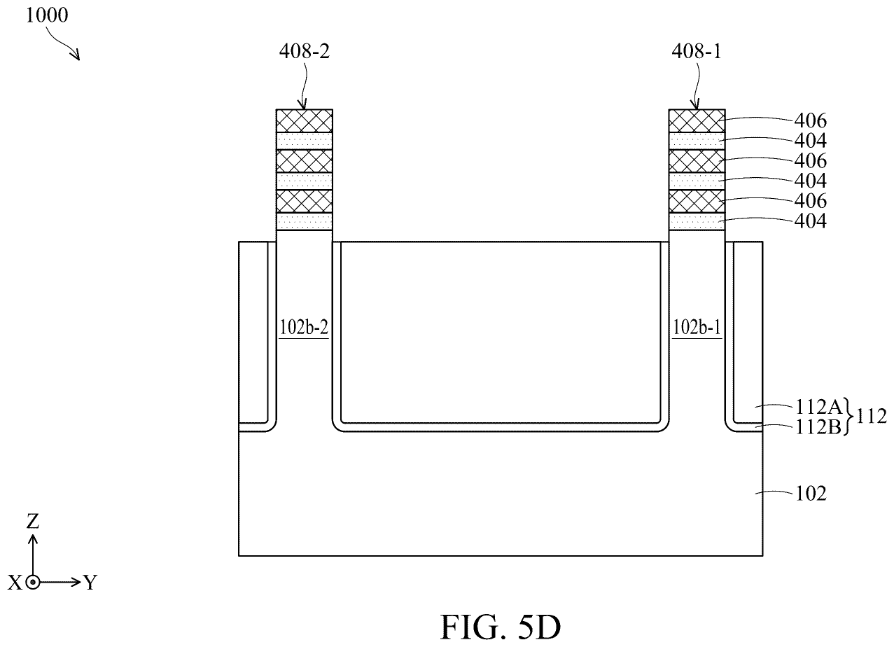

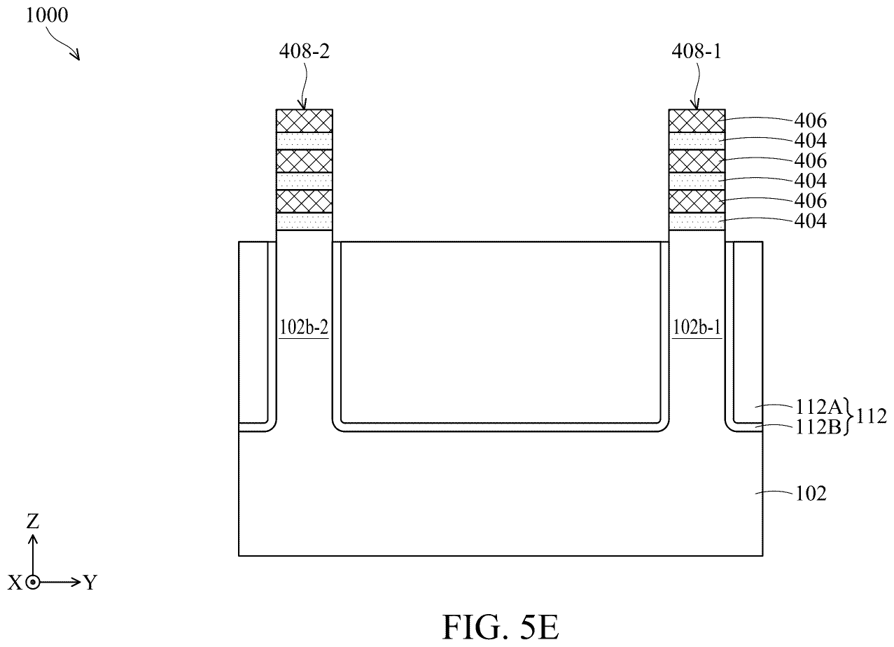

FIGS. 4 to 13E show the formation of the semiconductor structure 100. FIG. 4 is a perspective view of a workpiece 1000 at a fabrication stage for the semiconductor structure 100, in accordance with some embodiments of the present disclosure. FIGS. 5A, 6A, 7A, 8A, 9A, 10A, 11A, 12A, and 13A illustrate top views (or layouts) of the workpiece 1000 at various fabrication stages for the semiconductor structure 100, in accordance with some embodiments of the present disclosure. FIGS. 5B, 6B, 7B, 8B, 9B, 10B, 11B, 12B, and 13B illustrate X-Z cross-sectional views of the workpiece 1000 at various fabrication stages along lines B-B′ of FIGS. 5A to 13A, respectively, in accordance with some embodiments of the present disclosure. FIGS. 5C, 6C, 7C, 8C, 9C, 10C, 11C, 12C, and 13C illustrate X-Z cross-sectional views of the workpiece 1000 at various fabrication stages along lines C-C′ of FIGS. 5A to 13A, respectively, in accordance with some embodiments of the present disclosure. FIGS. 5D, 6D, 7D, 8D, 9D, 10D, 11D, 12D, and 13D illustrate Y-Z cross-sectional views of the workpiece 1000 at various fabrication stages along lines D-D′ of FIGS. 5A to 13A, respectively, in accordance with some embodiments of the present disclosure. FIGS. 5E, 6E, 7E, 8E, 9E, 10E, 11E, 12E, and 13E illustrate Y-Z cross-sectional views of the workpiece 1000 at various fabrication stages along lines E-E′ of FIGS. 5A to 13A, respectively, in accordance with some embodiments of the present disclosure.

Referring to FIG. 4, the workpiece 1000 is provided. The workpiece 1000 may include the substrate 102 discussed above and a stack 404 over the substrate 102. In some embodiments, the substrate 102 contains a semiconductor material, such as bulk silicon (Si). Alternatively or additionally, in some other embodiments, another elementary semiconductor, such as germanium (Ge) in a crystalline structure, may also be included in the substrate 102. The substrate 102 may also include a compound semiconductor, such as silicon germanium (SiGe) or a III-V semiconductor material. Example III-V semiconductor materials may include silicon carbide (SiC), indium arsenide (InAs), indium antimonide (InSb), indium phosphide (InP), gallium arsenide (GaAs), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and/or indium gallium arsenide (InGaAs), or combinations thereof. The substrate 102 may also include an insulating layer, such as a silicon oxide layer, to have a semiconductor-on-insulator substrate, such as Si-on-insulator (SOI), SiGe-on-insulator (SGOI), Ge-on-insulator (GOI) substrates.

In some embodiments, the substrate 102 may include various doped regions configured according to design requirements of GAA transistors. In some embodiments, the substrate 102 may include a doped region 102W (also referred to as a well region). The doped region 102W may be an n-type doped region (also referred to as an n-well) or a p-type doped region (also referred to as a p-well), and the n-type doped region is configured for a p-type metal-oxide-semiconductor (PMOS) transistor and the p-type doped region is configured for an n-type MOS (NMOS) transistor. N-type doped region is doped with n-type dopants, such as phosphorus (P), arsenic (As), other n-type dopant, or combinations thereof. P-type doped region is doped with p-type dopants, such as boron (B), indium (In), other p-type dopant, or combinations thereof.

In the present embodiment, the substrate 102 shows one doped region 102W. In other embodiments, substrate 102 may include multiple doped regions formed with a combination of p-type dopants and n-type dopants. An ion implantation process, a diffusion process, and/or other suitable doping process can be performed to form the various doped regions. In some embodiments, n-type doped region has an n-type dopant concentration of about 5×10¹⁶ cm⁻³ to about 5×10¹⁹ cm⁻³, and p-type doped region has a p-type dopant concentration of about 5×10¹⁶ cm⁻³ to about 5×10¹⁹ cm⁻³. Because the workpiece 1000 will be fabricated into a semiconductor structure 100 upon conclusion of the fabrication processes, the workpiece 1000 may be referred to as the semiconductor structure 100 as the context requires.

The stack 402 includes semiconductor layers 404 and 406, and the semiconductor layers 404 and 406 are alternatingly stacked in the Z-direction. The semiconductor layers 404 and the semiconductor layers 406 may have different semiconductor compositions. The semiconductor layers 406 will become the nanostructures 110 discussed above in subsequent processes. Therefore, the semiconductor layers 406 and the nanostructures 110 are equivalent, in accordance with some embodiments. As such, the semiconductor layers 406 may include a semiconductor material as the semiconductor material of the nanostructures 110 discussed above, such as silicon, germanium, silicon carbide, silicon phosphide, gallium arsenide, gallium phosphide, indium phosphide, indium arsenide, and/or indium antimonide, silicon germanium (SiGe), SiPC, GaAsP, AlInAs, AlGaAs, GaInAs, GaInP, and/or GaInAsP. In some embodiments, semiconductor layers 404 are formed of silicon germanium (SiGe) and the semiconductor layers 406 are formed of silicon (Si). In these embodiments, the additional germanium content in the semiconductor layers 404 allow selective removal or recess of the semiconductor layers 404 without substantial damages to the semiconductor layers 406, so that the semiconductor layers 404 are also referred to as sacrificial layers.

In some embodiments, the semiconductor layers 404 and 406 are epitaxially grown over (on) the substrate 102 using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized. The semiconductor layers 404 and the semiconductor layers 406 are deposited alternatingly, one-after-another, to form the stack 402.

It should be noted that three (3) layers of the semiconductor layers 404 and three (3) layers of the semiconductor layers 406 are alternately and vertically arranged (or stacked) as shown in FIG. 4, which are for illustrative purposes only and not intended to be limiting beyond what is specifically recited in the claims. The number of layers depends on the desired number of channel members for the semiconductor device. In some embodiments, there may be from 2 to 10 semiconductor layers 404 alternating with 2 to 10 semiconductor layers 406 in the stack 402.

Referring to FIGS. 5A to 5E, the substrate 102 and the stack 402 are then patterned to form the active areas 104 discussed above with fins 408 (including a fin 408-1 in the active area 104-1 and a fin 408-2 in the active area 104-2) over the substrate 102. For patterning purposes, the workpiece 1000 may also include a hard mask layer over the stack 402 before the patterning of the substrate 102 and the stack 402. The hard mask layer may be a single layer or a multi-layer. In some embodiments, the hard mask 110 is a single layer and includes a silicon germanium layer. In some embodiments, the hard mask layer is a multi-layer and includes a silicon nitride layer and a silicon oxide layer over the silicon nitride layer. In some other embodiments, the hard mask layer is a multi-layer and includes a silicon germanium layer and a silicon layer over the silicon germanium layer.

As shown in FIGS. 5A to 5E, each of the fins 408 in the active areas 104 includes a base fin (e.g., the base fins 102b-1 and 102b-2 discussed above) formed from a portion of the substrate 102 and a stack portion formed from the stack 402 over the base portion. In some aspects, the base fins 102b-1 and 102b-2 protrude from the substrate 102. Each of the fins 408 may include the semiconductor layers 404 and 406 alternating stacked in the Z-direction. The fins 408 extend lengthwise (e.g., longitudinally) in the X-direction, extend vertically in the Z-direction over the substrate 102, and are arranged in the Y-direction, as shown in FIGS. 5A to 5E. In some embodiments, widths of the fins 408 in the Y-direction are the same.

The fins 408 may be patterned using suitable processes including double-patterning or multi-patterning processes. For example, in some embodiments, a material layer of the hard mask layer is formed over the substrate 102 and patterned into the hard mask layer using a photolithography process. One or more etching processes are then performed to etch the stack 402 and top portions of the substrate 102 not covered by the hard mask layer to form the fins 408. The etching process may include dry etching, wet etching, reactive ion etching (RIE), and/or other suitable processes.

Still referring to FIGS. 5A to 5E, the isolation feature (or the isolation structure) 112 discussed above is formed over the substrate 102. More specifically, after the fins 408 are formed, the hard mask layer over the fins 408 is removed and the isolation feature 112 is then formed over the substrate 102. In some embodiments, the isolation structure 112 is formed between the fins 408. In some aspects, the isolation feature 112 is formed around the fins 408. More specifically, the isolation structure 112 are formed between and around the base fins (e.g., the base fins 102b-1 and 102b-2) of the fins 408. In other aspects, the isolation feature 112 is formed on opposite sides of the fins 408 (the semiconductor layers 404 and 406) in the Y-direction.

The isolation feature 112 may include different structures, such as shallow trench isolation (STI) structures and/or deep trench isolation (DTI) structures. In some embodiments, the isolation features 112 may also be referred to as shallow trench isolation (STI) feature. As discussed above, the isolation feature 112 may have a multi-layer structure such as one or more liner layer over the substrate 102 and a filling layer over the liner layer. More specifically, as shown in FIGS. 5A to 5E, the isolation feature 112 is formed form the liner layer 112A and the dielectric material 112B (i.e., the filling layer). Specifically, after the fins 408 are formed, a dielectric layer for the liner layers 112A is conformally formed on sidewalls of the fins 408 and over the fins 408 and the substrate 102. In order to form high quality liner layer 112A, the dielectric layer for the liner layer 112A is formed by performing atomic layer deposition (ALD) processes. In some embodiments, the dielectric layer for the liner layer 112A includes silicon oxide (SiO₂). Therefore, the liner layer 112A may also be referred to as silicon oxide layer, oxide layer or liner oxide layer.

After the formation of the dielectric layer for the liner layer 112A, a dielectric material 112B is deposited over the workpiece 1000. As discussed above, the dielectric material 112B may include silicon oxide, silicon nitride, silicon oxynitride, other suitable isolation material (for example, including silicon, oxygen, nitrogen, carbon, or other suitable isolation constituent), or a combination thereof. In various embodiments, the dielectric material 112B may be deposited by a CVD, a subatmospheric CVD (SACVD), a plasma-enhanced CVD (PECVD), a flowable CVD (FCVD), an ALD, a plasma-enhanced ALD (PEALD), spin-on coating, and/or other suitable process. The deposited dielectric material 112B is then thinned and planarized, for example by a chemical mechanical polishing (CMP) process. The planarized dielectric material 112B and the liner layer 112A 116B are further recessed by a dry etching process, a wet etching process, and/or a combination thereof to form the isolation feature 112. Furthermore, as shown in FIGS. 5A to 5E, the stack portions of the fins 408 rise above the isolation feature 112 while the base fins (e.g., the base fins 102b-1 and 102b-2) are surrounded by the isolation feature 112. In other words, top surfaces (or topmost surfaces) of the substrate 102 are higher than top surfaces of the isolation feature 112, as shown in FIGS. 5A to 5E.

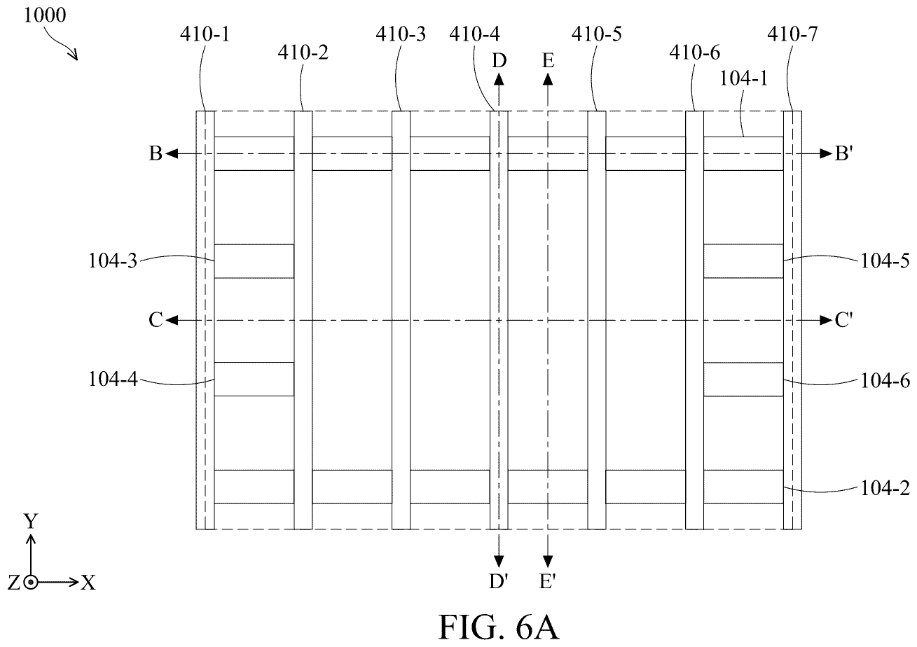

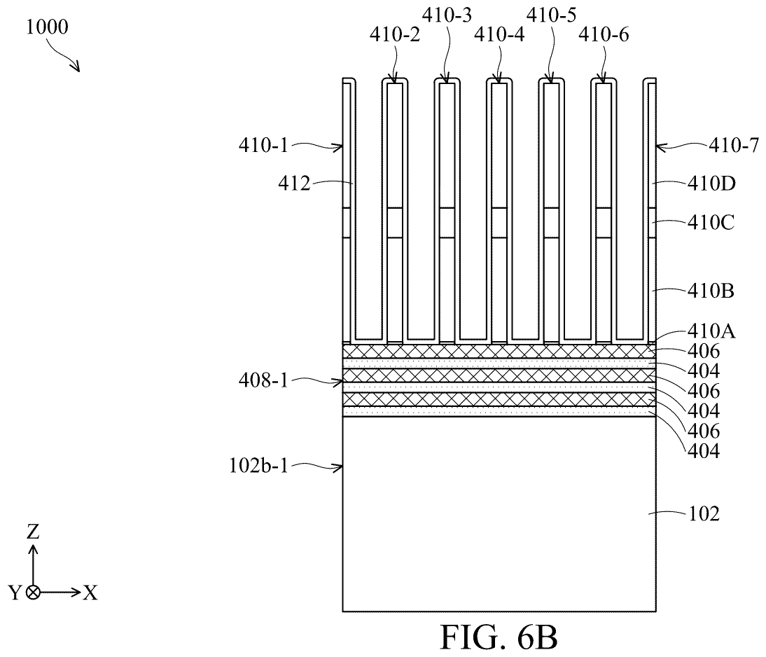

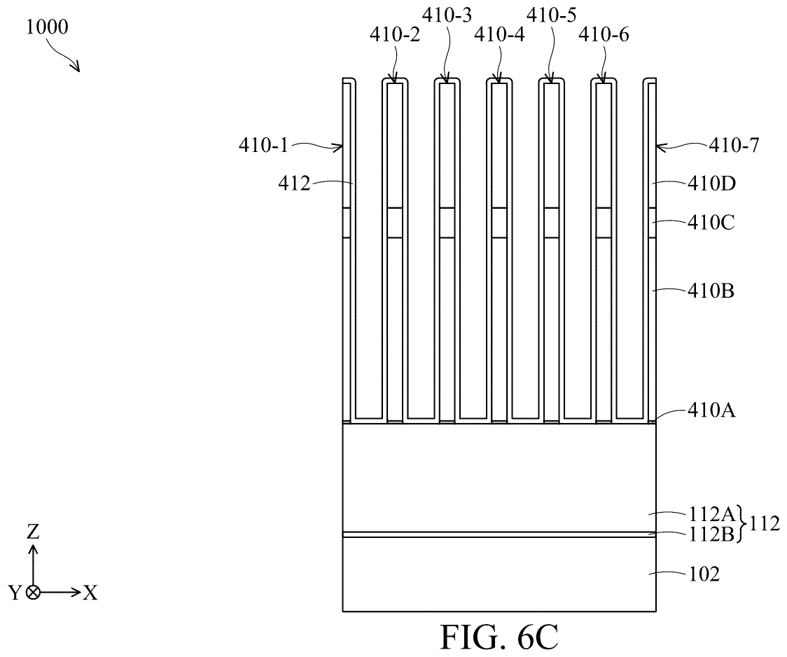

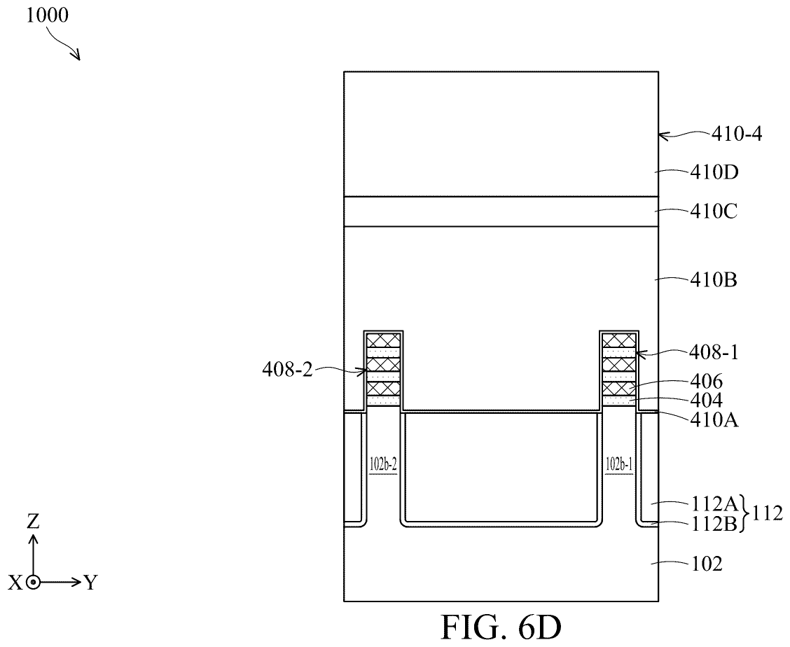

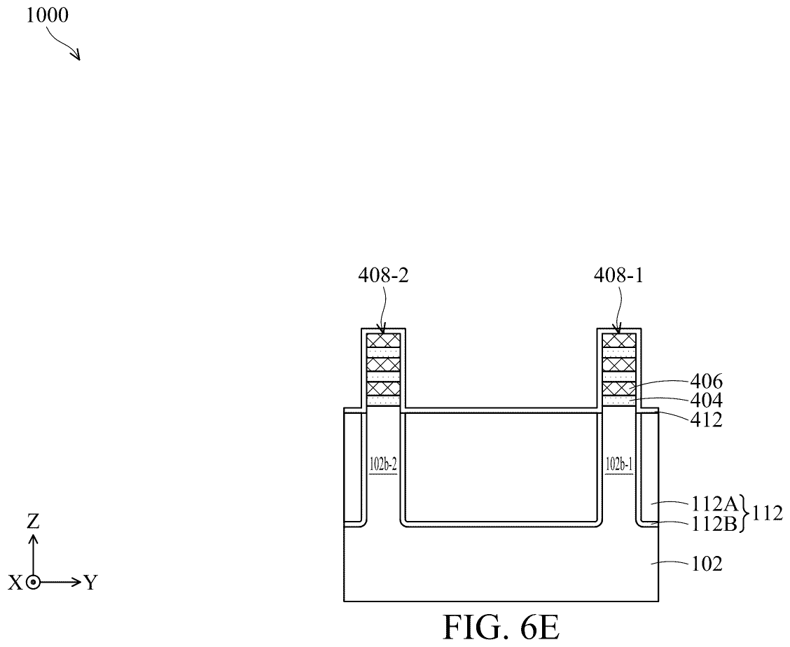

Referring to FIGS. 6A to 6E, dummy gate structures 410-1 to 410-7 (may be collectively referred to as dummy gate structures 410) may be formed over the fins 408 in the active areas 104, the isolation feature 112, and the substrate 102. The dummy gate structures 410 may be configured to extend lengthwise in the Y-direction and wrap around top surfaces and side surfaces of the fins 408, as shown in FIG. 6D. In some embodiments, the dummy gate structures 410 are arranged in the X-direction. In some embodiments, to form the dummy gate structures 410, a dummy interfacial material of a dummy interfacial layer 410A is first formed over the fins 408 and over the isolation feature 112. More specifically, the dummy interfacial material is conformally formed on sidewalls of the fins 408 and over top surfaces of the fins 408 and the isolation feature 112, as shown in FIG. 6D.

In some embodiments, the dummy interfacial layer 410A may include, for example, a dielectric material such as a nitride (e.g., silicon nitride, silicon oxynitride), a carbide (e.g., silicon carbide), an oxide (e.g., silicon oxide), or some other suitable material. Then, in some embodiments, a dummy gate material of a dummy gate electrode 410B is formed over the dummy interfacial material. The dummy gate material may include a conductive material selected from a group comprising of polysilicon, W, Al, Cu, AlCu, Ti, TiAlN, TaC, TaCN, TaSiN, Mn, Zr, TiN, Ta, TaN, Co, Ni, and/or combinations thereof. The dummy gate material and/or the dummy interfacial material may be formed by way of a thermal oxidation process and/or a deposition process (e.g., PVD, CVD, PECVD, and ALD).

Then, hard mask layers 410C and 410D are formed over the dummy gate material. In some embodiments, the hard mask layers 410C and 410D may be formed using photolithography and removal (e.g., etching) processes. In some embodiments, the hard mask layers 410C and 410D may include photoresist materials or hard mask materials. In some embodiments, the hard mask layer 410C may be a silicon nitride layer and the hard mask layer 410D may be a silicon oxide layer. After the formation of the hard mask layers 410C and 410D, lithography and etching processes may be performed to remove portions of the dummy gate material for the dummy gate electrode 410B and the dummy interfacial material for the dummy interfacial layer 410A that are not directly underlie the hard mask layers 410C and 410D, thereby forming the dummy gate structures 410 having the dummy interfacial layer 410A, the dummy gate electrode 410B, and the hard mask layers 410C and 410D. The dummy interfacial layer 410A may also be referred to as dummy gate dielectric. The dummy gate structure 410 may undergo a gate replacement process through subsequent processing to form metal gates, such as a high-k metal gate, as discussed in greater detail below.

FIGS. 6A to 6E shows seven dummy gate structures 410-1 to 410-7. The dummy gate structures 410 extend substantially parallel to one another, extend lengthwise in the Y-direction perpendicular to the X-direction, and are separated from each other in the X-direction, as shown in FIGS. 6A to 6E. As shown in FIGS. 6A to 6E, the dummy gate structures 410-3 to 410-5 are disposed over the active areas 104-1 and 104-2, the dummy gate structures 410-1 and 410-2 are disposed over the active areas 104-1, 104-3, 104-4, and 104-2, and the dummy gate structures 410-6 and 410-7 are disposed over the active areas 104-1, 104-5, 104-6, and 104-2.

Still referring to FIGS. 6A to 6E, after the formation of the dummy gate structures 410, a spacer layer 412 is formed on top surfaces and sidewalls of the dummy gate structures 410, over top surfaces of the fins 408, and on sidewalls of the fins 408. More specifically, in some embodiments, the spacer layer 412 may be formed by conformally depositing the spacer layer 412 (containing the dielectric material) over the isolation feature 112, the fins 408, and dummy gate structures 410. Additionally or alternatively, the formation of the spacer layer 412 may also involve chemical oxidation, thermal oxidation, ALD, CVD, and/or other suitable methods. The spacer layer 412 may include silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, or combinations thereof. The spacer layer 412 may include a single layer or a multi-layer structure.

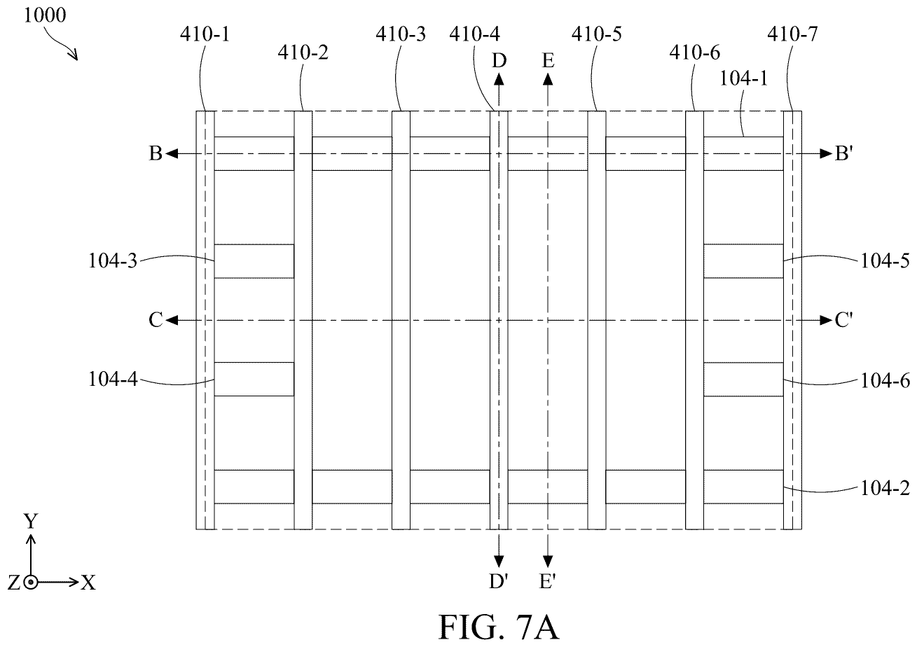

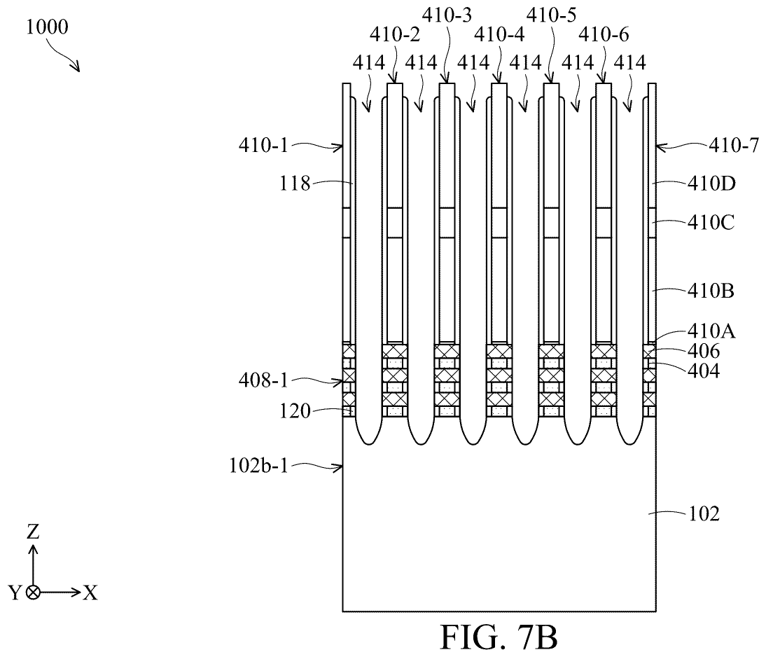

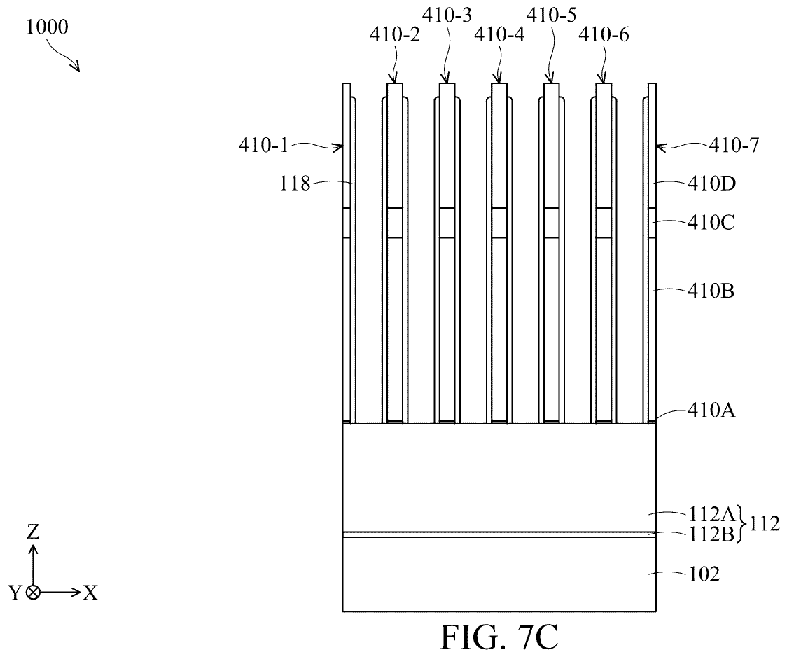

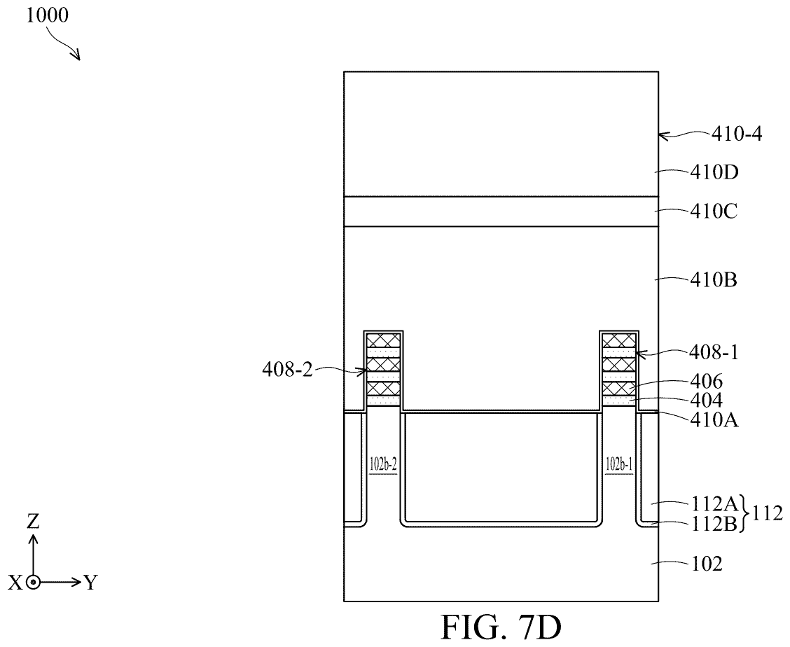

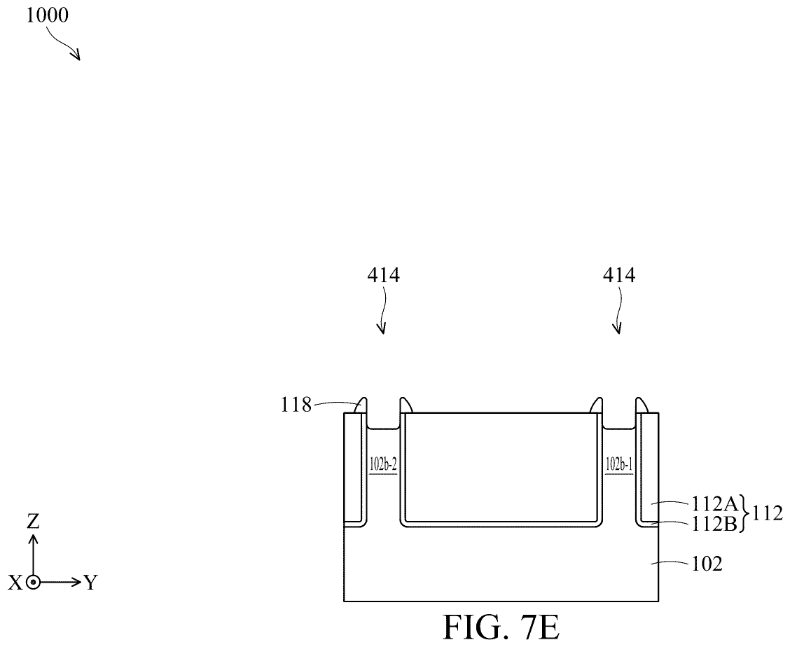

Referring to FIGS. 7A to 7E, the fins 408 are recessed to form source/drain trenches 414 in the fins 408 (or passing through the semiconductor layers 404 and 406) exposed by the dummy gate structures 410. The source/drain trenches 414 are also formed on opposite sides of the dummy gate structures 410 in the X-direction, as shown in FIG. 7B. More specifically, the source/drain trenches 414 may be formed by performing one or more etching processes to remove portions of the spacer layer 412, the semiconductor layers 404, the semiconductor layers 406, and the substrate 102 that do not vertically overlap or be covered by the dummy gate structures 410. In some embodiments, a single etchant may be used to remove the portions of the spacer layer 412, the semiconductor layers 404, the semiconductor layers 406, and the substrate 102, whereas in other embodiments, multiple etchants may be used to perform the etching process. As shown in FIGS. 7B and 7E, portions of the substrate 102 are etched so that the substrate 102 has concave surfaces, and the concave surfaces are lower than the top surfaces of the isolation feature 112 (shown in FIG. 7E).

Furthermore, as discussed above, the portions of the spacer layer 412 are removed, so that remain portions of spacer layer 412 become the gate spacers 118 discussed above on opposite sides of the dummy gate structures 410 in the X-direction, as shown in FIG. 7B. As shown in FIG. 7E, portions of the spacer layer 412 on the sidewall surfaces of the fins 408 in the Y-direction (shown in FIG. 6E) remain in the source/drain trenches 414 and over the isolation feature 112 to become the gate spacers 118. The gate spacers 118 may also be interchangeably referred to as the top spacers.

Still referring to FIGS. 7A to 7E, the inner spacers 120 discussed above are formed under the gate spacers 118 and between the semiconductor layers 406 as well as between the semiconductor layers 406 and the substrate 302. In the formation of the inner spacers 120, side portions of the semiconductor layers 404 are removed via a selective etching process. More specifically, the selective etching process is performed that selectively etches the side portions of the semiconductor layers 404 below the gate spacers 118 through the source/drain trenches 414, with minimal (or no) etching of semiconductor layers 406, the gate spacers 118, the isolation feature 112, and the substrate 102, such that gaps are formed vertically between (the side portions of) the semiconductor layers 406 in the Z-direction as well as vertically between (the side portions of) the semiconductor layers 406 and the substrate 102 in the Z-direction, and below the gate spacers 118. The etching process is configured to laterally etch (e.g., along the X-direction) the semiconductor layers 404 below the gate spacers 118. The selective etching process is a dry etching process, a wet etching process, other suitable etching process, or combinations thereof.

Still referring to FIGS. 7A to 7E, the inner spacers 120 discussed above are formed to fill the gaps. The inner spacers 120 are between the semiconductor layers 406 in the Z-direction and between the (bottommost) semiconductor layers 406 and the substrate 102 direct under the gate spacers 118 in the Z-direction. In some embodiments, sidewalls of the inner spacers 120 are aligned to the sidewalls of the gate spacers 118 and the semiconductor layers 406, as shown in FIG. 7B. In order to form the inner spacers 120, a deposition process forms a spacer layer into the source/drain trenches 414 and the gaps, such as CVD, PVD, ALD, HDPCVD, MOCVD, RPCVD, PECVD, LPCVD, ALCVD, APCVD, other suitable methods, or combinations thereof. The spacer layer partially (and, in some embodiments, completely) fills the source/drain trenches 414. The deposition process is configured to ensure that the spacer layer fills the gaps between the semiconductor layers 406 as well as between the semiconductor layer 406 and the substrate 102 under the gate spacers 118. An etching process is then performed that selectively etches the spacer layer to form the inner spacers 120 discussed above (as shown in FIGS. 2B and 7B) with minimal (to no) etching of the semiconductor layer 406, the substrate 102, the dummy gate structure 410, and the gate spacers 118.

The spacer layer (and thus the inner spacers 120) includes a material that is different than a material of the semiconductor layers 406 and a material of the gate spacers 118 to achieve desired etching selectivity during the etching process. In some embodiments, the inner spacers 120 include a dielectric material that includes silicon, oxygen, carbon, nitrogen, other suitable material, or combinations thereof (for example, silicon oxide (SiOₓ), silicon nitride (Si₃N₄), silicon carbon (SiC), silicon oxynitride (SiON), silicon oxycarbide (SiOC), silicon carbon nitride (SiCN), silicon oxycarbon nitride (SiOCN), air gap, or a combination thereof). In some embodiments, the inner spacers 120 include a low-k dielectric material (but having higher K value than the gate spacers 118, in accordance with some embodiments), such as those described herein.

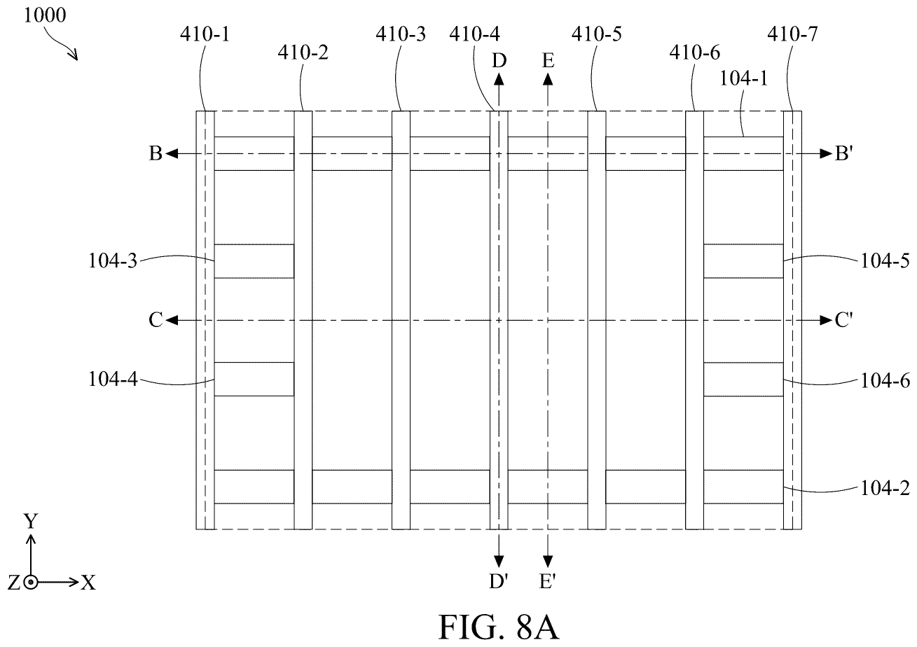

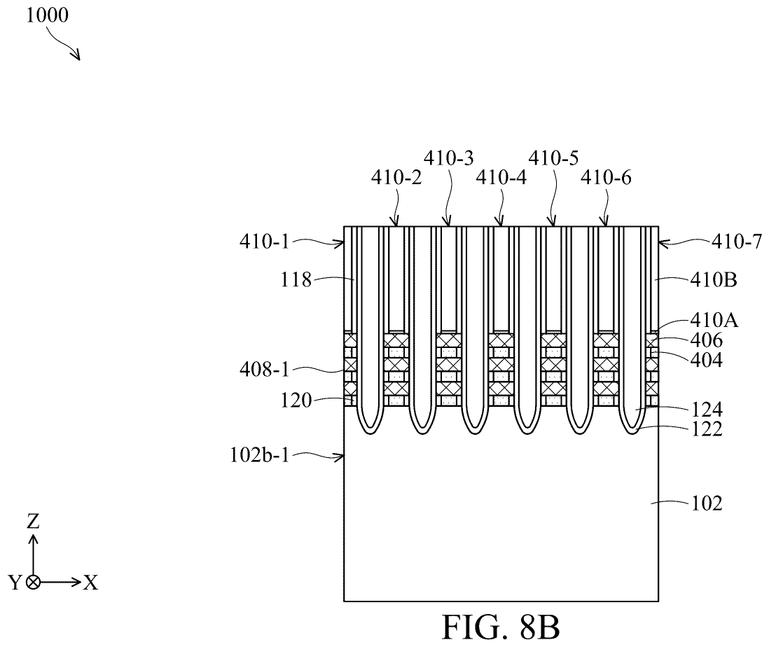

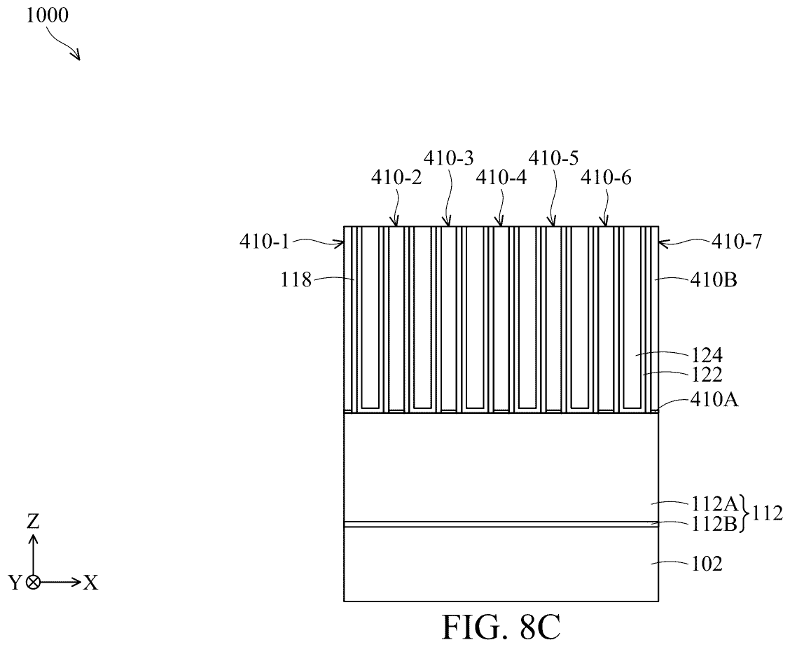

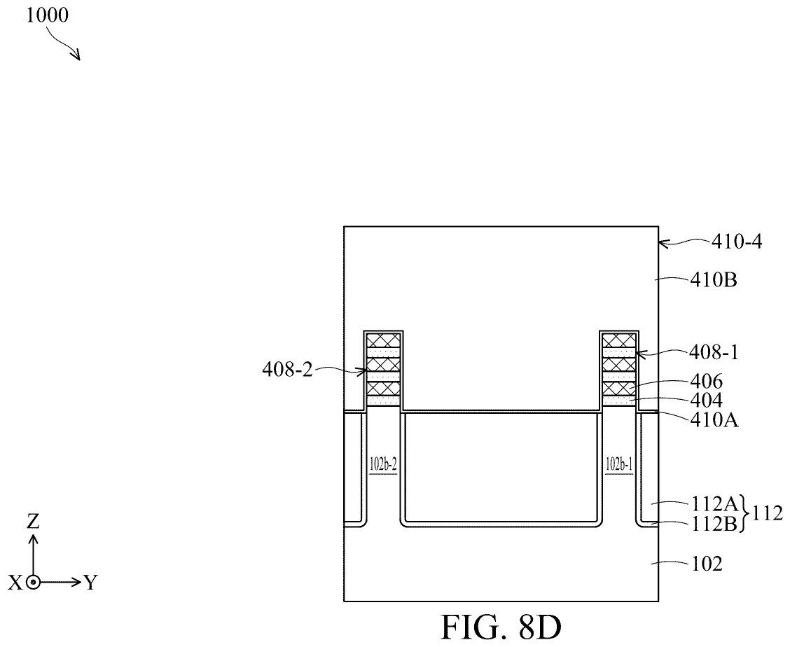

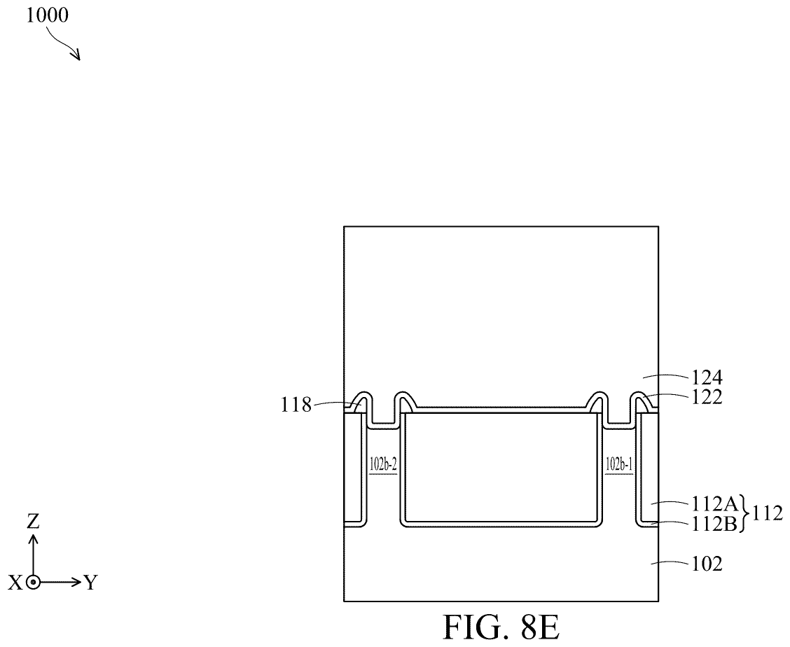

Referring to FIGS. 8A to 8E, the contact etch stop layer (CESL) 122 discussed above and the interlayer dielectric (ILD) layer 124 discussed above over the CESL 122 are formed to fill the spaces between the dummy gate structures 410, between the gate spacers 118, and in the source/drain trenches 414. More specifically, the CESL 122 is conformally formed on the sidewalls of the gate spacers 118, the semiconductor layers 406, the inner spacers 120, over the top surfaces of the substrate 102, the isolation feature 112, and the gate spacers 118, as shown in FIGS. 8B to 8E. The ILD layer 124 is then formed over the CESL 122 to fill remaining spaces between (or inside) the CESL 122, between the gate spacers 118 and in the source/drain trenches 414.

It should be noted that the formation of the source/drain features is omitted and the CESL 122 is formed on the sidewalls of the semiconductor layers 406 (and thus on the sidewalls of the nanostructures 110). Therefore, the transistors formed in the active areas 104-1 to 104-6 are non-functional, as discussed above. In some embodiments, the active areas 104-1 to 104-6 may also be referred to as dummy active areas. As shown in FIGS. 8B and 8C, the CESL 122 and the ILD layer 124 are also formed on opposite sides of the dummy gate structures 410 in the X-direction. In other words, the CESL 122 and the ILD layer 124 are also between dummy gate structures 410 in the X-direction, as shown in FIGS. 8B and 8C.

Subsequent to the deposition of the CESL 122 and the ILD layer 124, a CMP process and/or other planarization process is performed on the CESL 122, the ILD layer 124, the gate spacers 118, and the hard mask layers 410C and 410D of the dummy gate structures 410 until the top surfaces of the dummy gate electrodes 410B are exposed. Therefore, the heights of the gate spacers 118 and the dummy gate structures 410 are reduced. Furthermore, the top surfaces of the gate spacers 118, the dummy gate structures 410 (the dummy gate electrodes 410B), the CESL 122, and the ILD layer 124 are substantially level with each other (i.e., coplanar), as shown in FIGS. 8B and 8C.

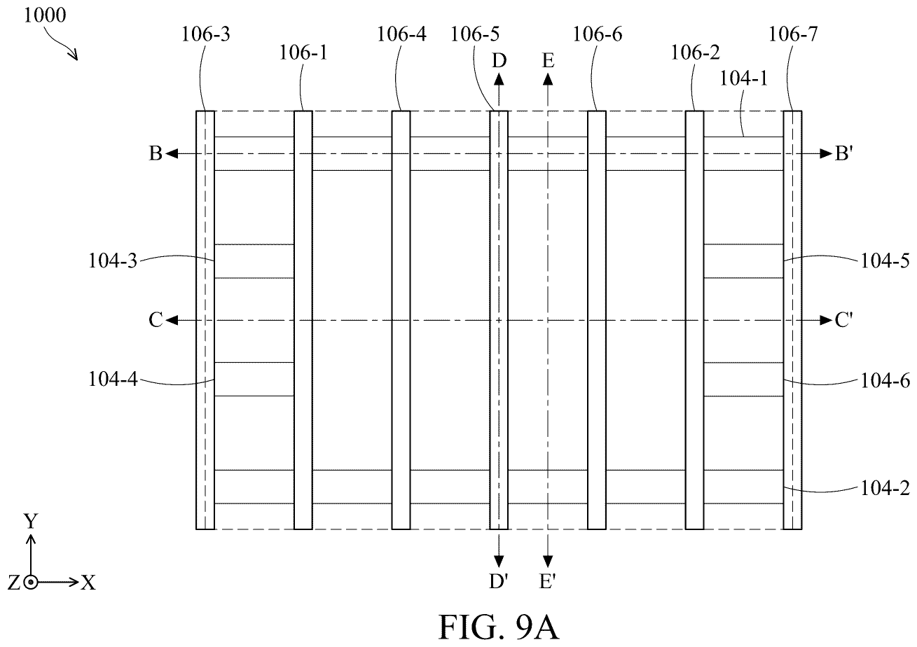

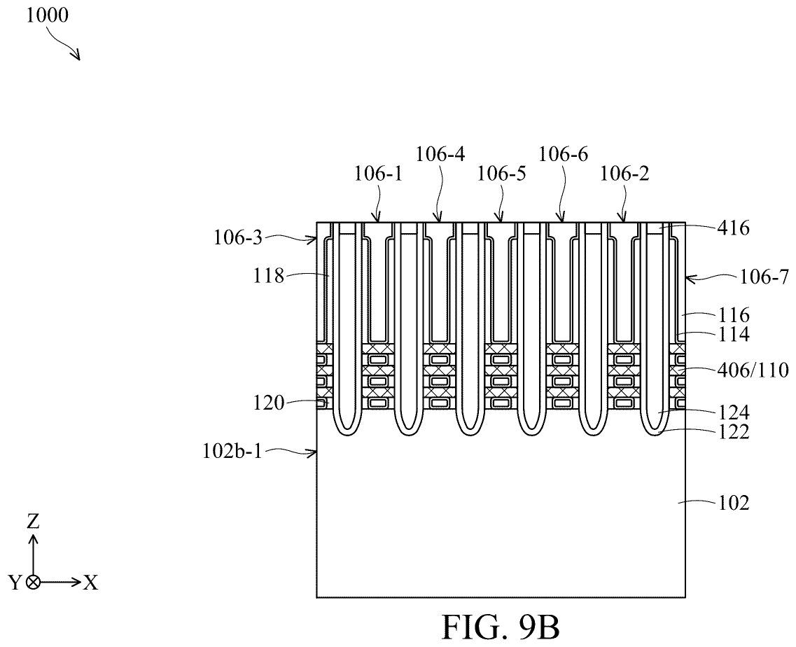

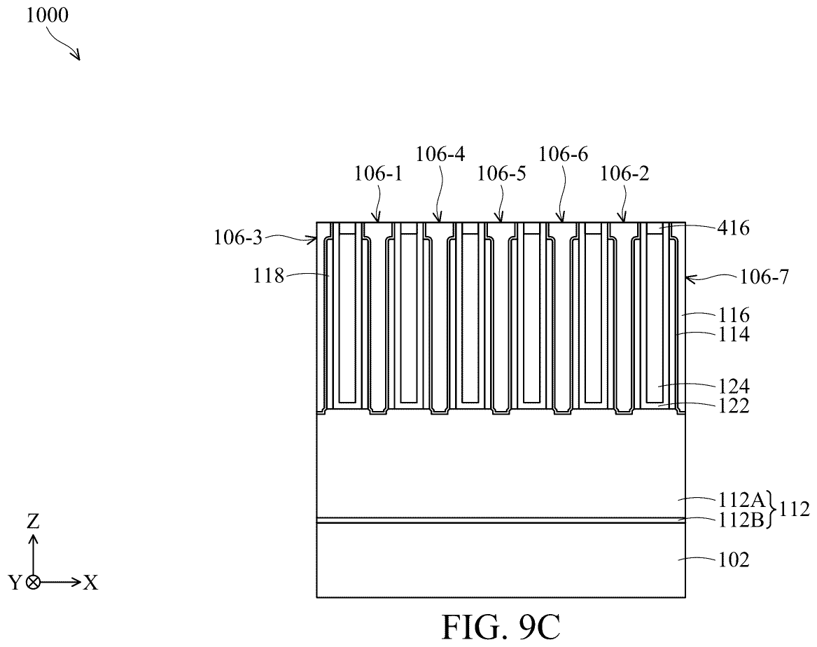

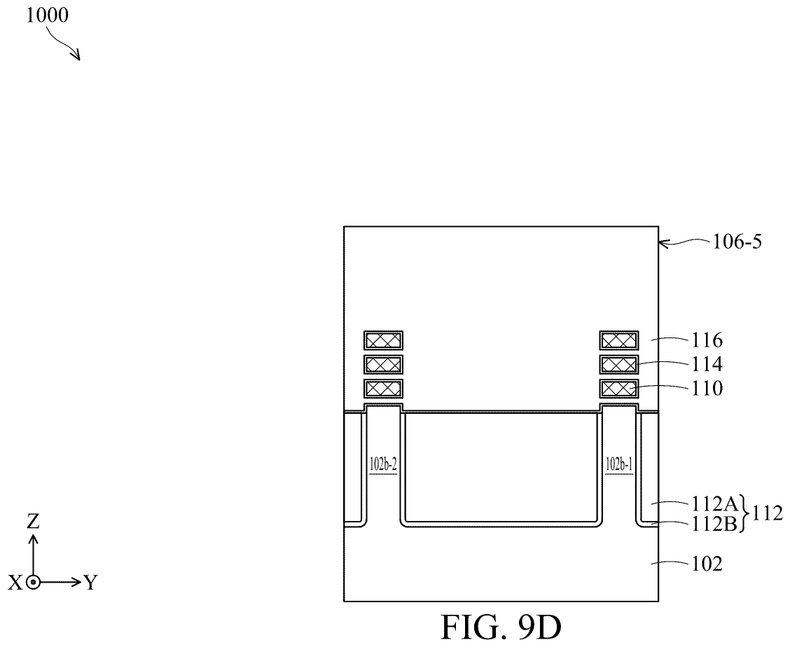

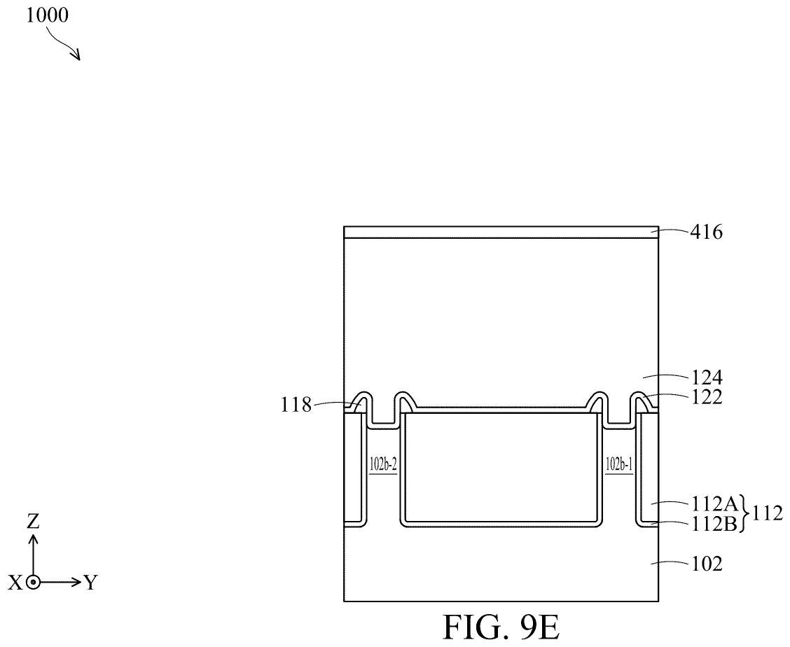

Referring to FIGS. 9A to 9E, the ILD layer 124 is recessed to a level below the top surface of the dummy gate electrodes 410B, and then an ILD protection layer 416 is formed over the ILD layer 124 to protect the ILD layer 124 from subsequent etching processes. As such, the ILD layer 124 is surrounded by the CESL 122 and the ILD protection layer 416. In some embodiments, the ILD protection layer 416 includes a material that is the same as or similar to that in the CESL 122. In some other embodiments, the ILD protection layer 416 includes a dielectric material such as Si₃N₄, SiCN, SiOCN, SiOC, a metal oxide such as HrO₂, ZrO₂, hafnium aluminum oxide, hafnium silicate, or other suitable material, and may be formed by CVD, PVD, ALD, or other suitable methods.

Still referring to FIGS. 9A to 9E, the dummy gate structures 410-1 to 410-7 and the semiconductor layers 404 are replaced with the gate structures 106-1 to 106-7. More specifically, the dummy gate structures 410-1, 410-2, 410-3, 410-4, 410-5, 410-6, and 410-7 are respectively replaced with the gate structures 106-3, 106-1, 106-4, 106-5, 106-6, 106-2, and 106-7. In order to form the gate structures 106-1 to 106-7, the dummy gate structures 410 are selectively removed through any suitable lithography and etching processes. In some embodiments, the lithography process may include forming a photoresist layer (resist), exposing the resist to a pattern, performing a post-exposure bake process, and developing the resist to form a masking element, which exposes a region including the dummy gate structures 410. Then, the dummy gate structures 410 are selectively etched through the masking element. Etch selectivity may be achieved by selecting the appropriate etching chemicals, and the dummy gate structures 410 may be removed without substantially affecting the semiconductor layers 406, the gate spacers 118, the inner spacers 120, the isolation feature 112, and the substrate 102. The removal of the dummy gate structures 410 creates gate trenches exposing the top surfaces of the topmost semiconductor layers 406 underlies the dummy gate structures 410.

After the removal of the dummy gate structures 410, the semiconductor layers 404 in the fins 408 are selectively removed through the gate trenches, using a wet or dry etching process for example, so that the semiconductor layers 406 in the fins 410 are exposed in the gate trenches to form the nanostructures 110 discussed above. Therefore, the semiconductor layers 406 and the nanostructures 110 are equivalent, and the semiconductor layers 406 may be referred to as the nanostructures 110 as the context requires. Such a process may also be referred to as a wire release process, a nanowire release process, a nanosheet release process, a nanowire formation process, a nanosheet formation process, or a wire formation process. In some embodiments, the removal of the semiconductor layers 404 causes the exposed semiconductor layers 406 (the nanostructures 110) to be spaced apart from each other in the vertical direction (e.g., in the Z-direction). The exposed semiconductor layers 406 extend longitudinally in the horizontal direction (e.g., in the X-direction), and each is in contact with the CESL 122, as shown in FIG. 9B.

Still referring to FIGS. 9A to 9E, the gate structures 106 are formed in the gate trenches to wrap around the semiconductor layers 406 (the nanostructures 110). The gate structures 106 each includes the gate dielectric layer 114 and the gate electrode layer 116 over the gate dielectric layer 114, as discussed above. In some embodiments, the gate dielectric layers 114 are formed to wrap around each of the semiconductor layers 406 (the nanostructures 110). Additionally, the gate dielectric layers 114 are also formed on sidewalls of the inner spacers 120 and the gate spacers 118.

The gate electrode layers 116 are then formed to fill the remaining spaces of the gate trenches, and over the gate dielectric layers 114 in such a way that each of the gate electrode layers 116 each wraps around the semiconductor layers 406 (the nanostructures 110), the gate dielectric layer 114, and the interfacial layers (if present). The gate electrode layers 116, the gate dielectric layers 114, and the interfacial layers (if present) may be collectively called as the gate structures 106 wrapping around the semiconductor layers 406 (the nanostructures 110), as discussed above.

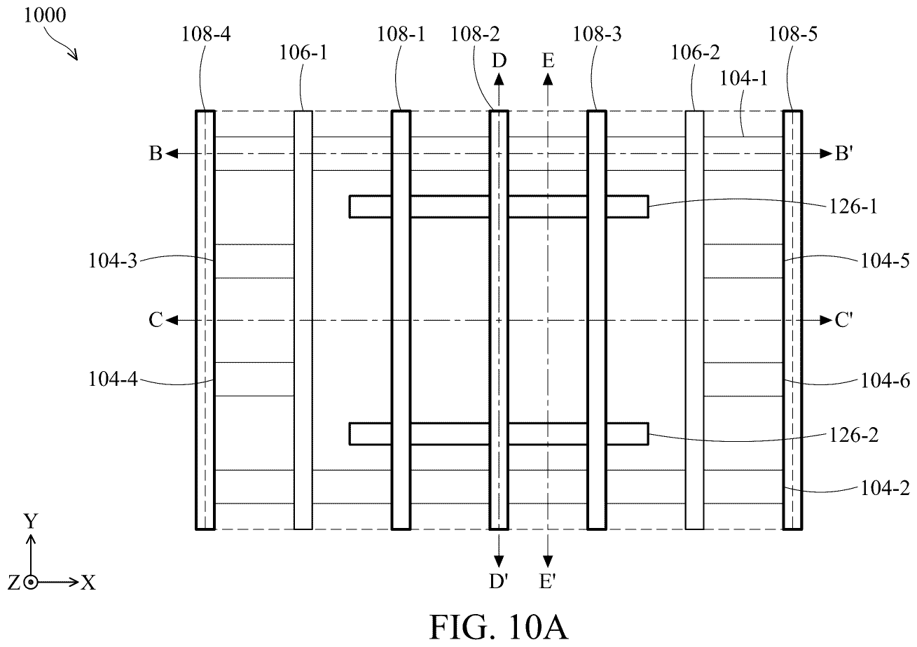

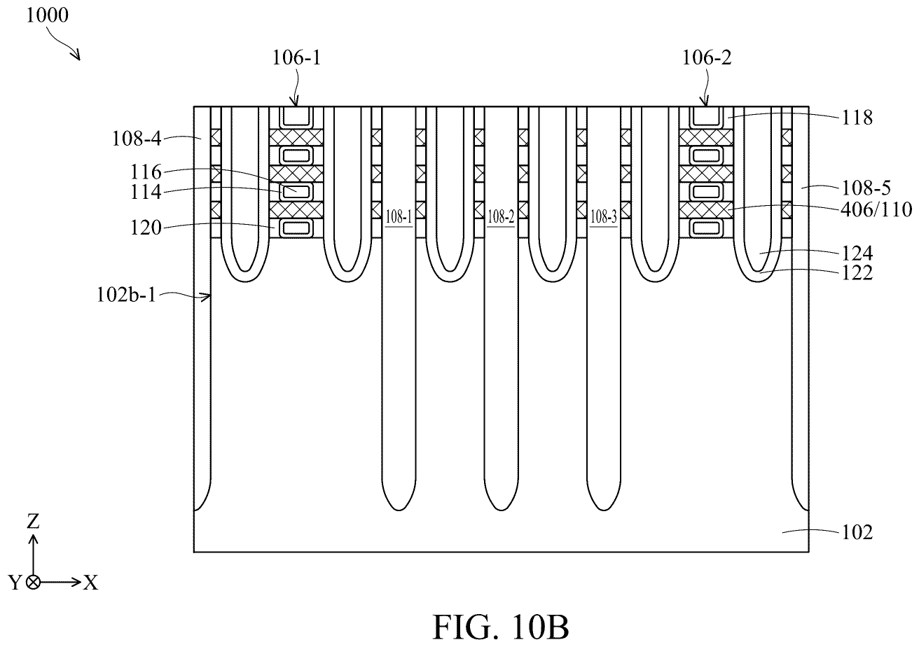

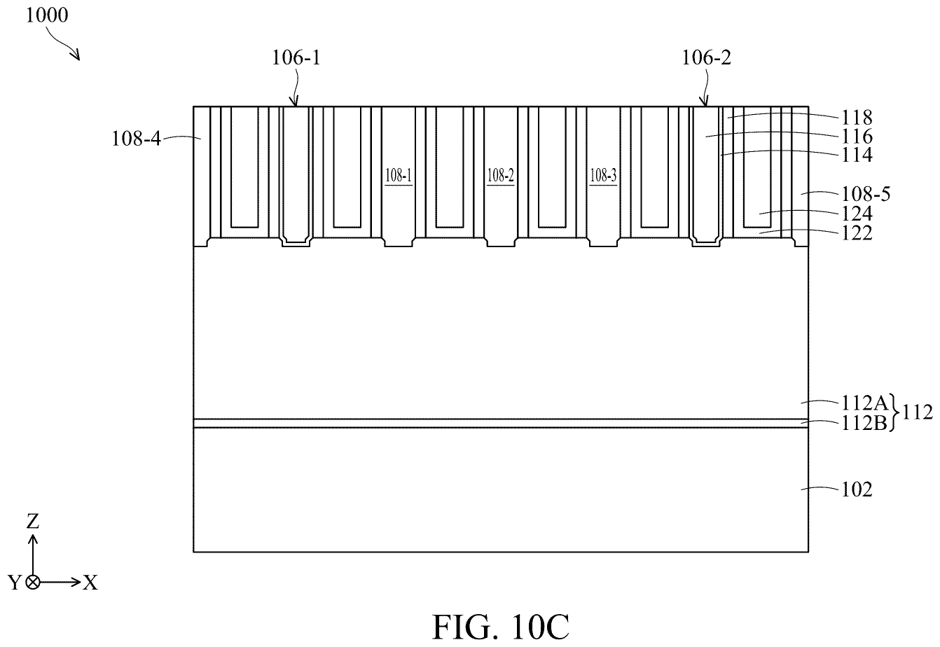

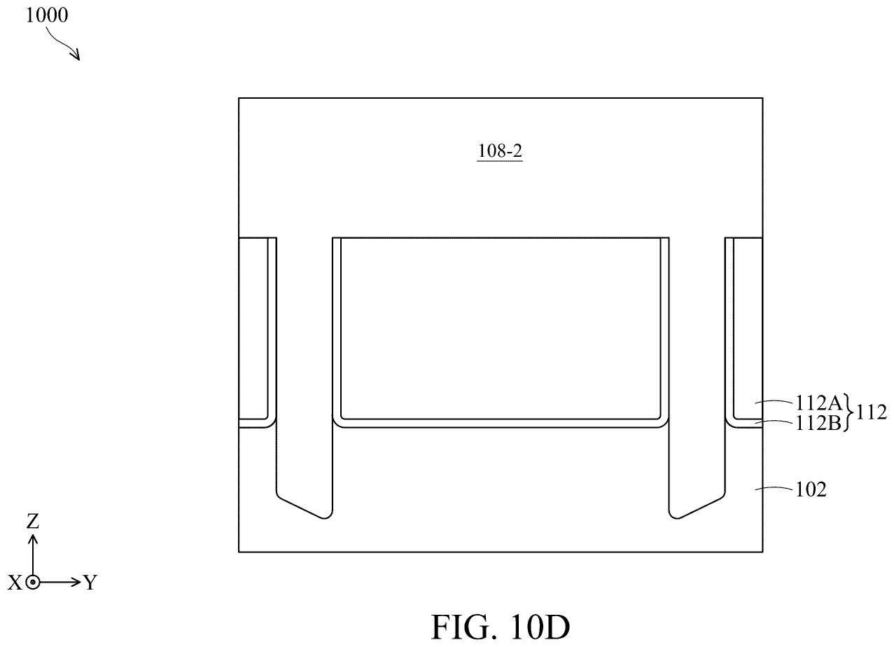

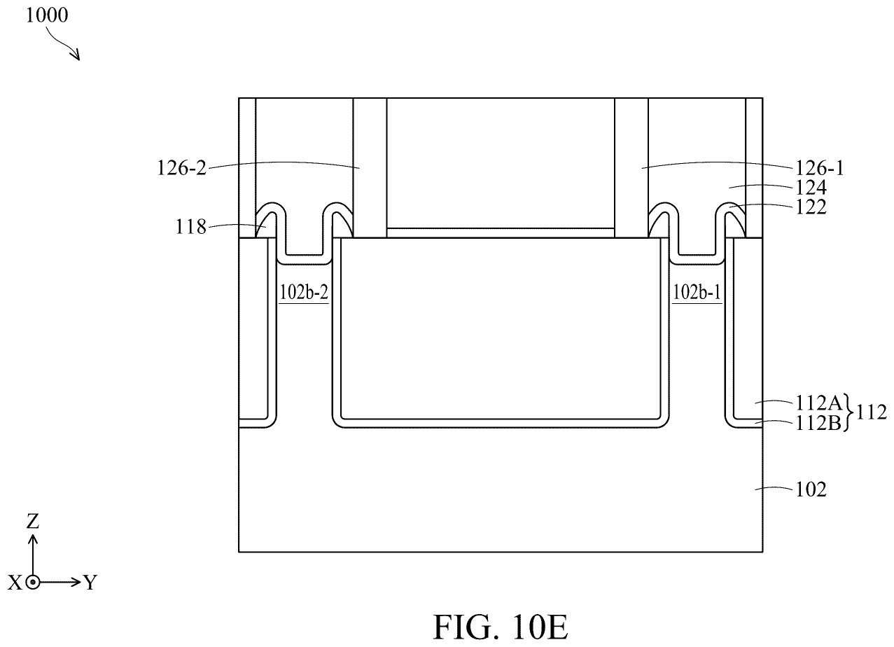

Referring to FIGS. 10A to 10E, the dielectric structures 108 discussed above are formed to replace portions of the gate structures 106 and the semiconductor layers 406 wrapped around by the gate structures 106. More specifically, the gate structures 106-3, 106-4, 106-5, 106-6, and 106-7 and the semiconductor layers 406 (the nanostructures 110) below them are respectively replaced with the dielectric structures 108-4, 108-1, 108-2, 108-3, and 108-5, as shown in FIGS. 10A to 10E. In order to form the dielectric structures 108, one or more lithography and etching processes may be performed to remove the portions of the gate structures 106 (the gate structures 106-3, 106-4, 106-5, 106-6, and 106-7) and the semiconductor layers 406 (the nanostructures 110 in regions to be formed the dielectric structures 108, and then the dielectric material for the dielectric structures 108 discussed above are formed in the regions to form the dielectric structures 108. As shown in FIGS. 10B and 10D, portions of the substrate 102 in the regions to be formed the dielectric structures 108 are also removed during the formation of the dielectric structures 108. Therefore, top surfaces of the substrate 102 in contact with the dielectric structures 108 are lower than other top surfaces of the substrate 102.

Due to the dielectric structures 108 are formed to replace the gate structures 106, the dielectric structures 108 are also extend lengthwise in the Y-direction. Furthermore, the dielectric structures 108 are also formed between the gate spacers 118 and the inner spacers 120 in the X-direction, as shown in FIG. 10B. In some embodiments, the dielectric structures 108 are also in contact with sidewalls of the isolation feature 112 in the Y-direction, as shown in FIG. 10D. As discussed above, the dielectric structures 108-1 to 108-3 are formed between the gate structures 106-1 and 106-2 in the X-direction, the dielectric structures 108-4 and 108-1 are formed on opposite sides of the gate structure 106-1 in the X-direction, and the dielectric structures 108-3 and 108-5 are formed on opposite sides of the gate structure 106-2 in the X-direction.

Still referring to FIGS. 10A to 10E, the dielectric structures 126-1 and 126-2 discussed above are formed. As shown in FIG. 10A, the dielectric structure 126-1 is formed adjacent to the active area 104-1 in the Y-direction and the dielectric structure 126-2 is formed adjacent to the active area 104-2 in the Y-direction. In some embodiments, the dielectric structures 126-1 and 126-2 are formed passing through the CESL 122 and the ILD layer 124, as shown in FIG. 10E. Furthermore, the dielectric structures 126-1 and 126-2 are formed over and in contact with the isolation feature 112, as shown in FIG. 10. As discussed above, the space/area between the dielectric structures 126-1 and 126-2 in the Y-direction will be used for disposing the feed-through structure/cell.

In some embodiments, the dielectric structures 126-1 and 126-2 extend lengthwise in the X-direction. Furthermore, in the formation of the dielectric structures 126-1 and 126-2, one or more lithography and etching processes may be performed to remove the portions of the CESL 122 and the ILD layer 124 in regions to be formed the dielectric structures 126-1 and 126-2, and then the dielectric material for the dielectric structures 126-1 and 126-2 discussed above are formed in the regions to form the dielectric structures 126-1 and 126-2. However, the etching processes do not remove the dielectric structures 108-1 to 108-3. As such, the dielectric structures 126-1 and 126-2 are formed as non-continuous features, as discussed above. The dielectric structures 126-1 and 126-2 are formed as multiple segments between the dielectric structures 108-1 to 108-3, as shown in FIG. 10B. Therefore, as shown in FIG. 10B, each of the dielectric structures 126-1 and 126-2 are formed as divided into multiple segments by the dielectric layers 108-1 to 108-3, as discussed above.

Subsequent to the formation of the dielectric structures 108 and 126, a CMP process and/or other planarization process is performed on the dielectric structures 108 and 126, the gate structures 106, the gate spacers 118, the CESL 122, the ILD layer 124, and the ILD protection layer 416. Therefore, the ILD protection layer 416 is removed and the heights of the dielectric structures 108 and 126, the gate structures 106, the gate spacers 118, the CESL 122, and the ILD layer 124 are reduced. Furthermore, the top surfaces of the dielectric structures 108 and 126, the gate structures 106, the gate spacers 118, the CESL 122, and the ILD layer 124 are substantially level with each other (i.e., coplanar), as shown in FIGS. 10A to 10E.

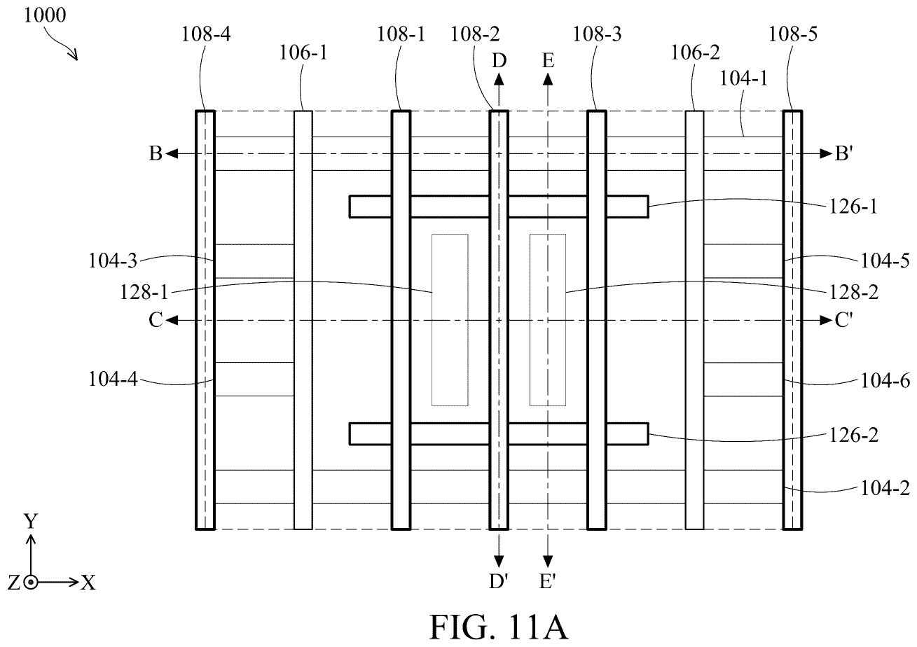

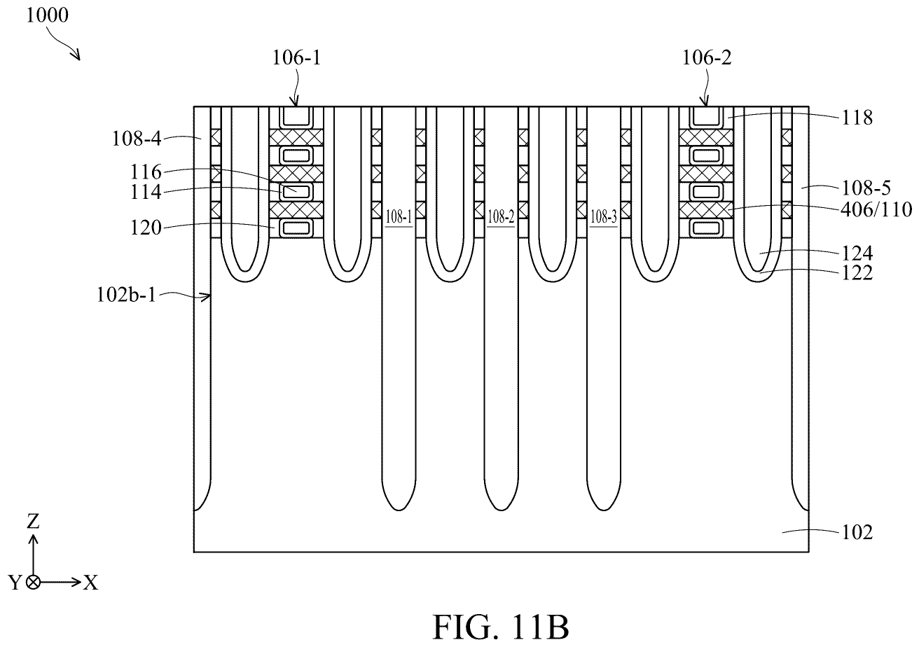

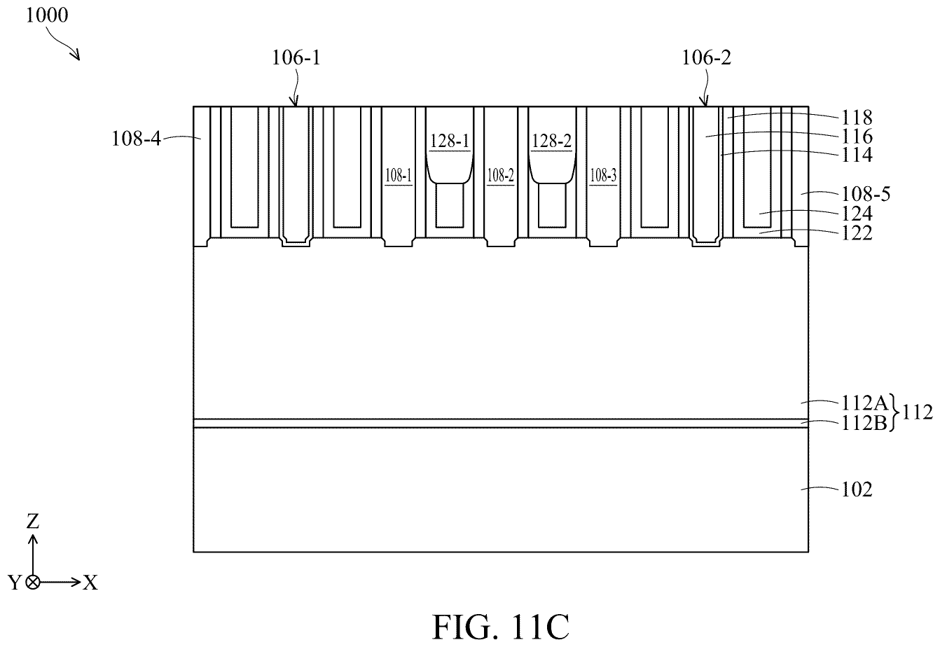

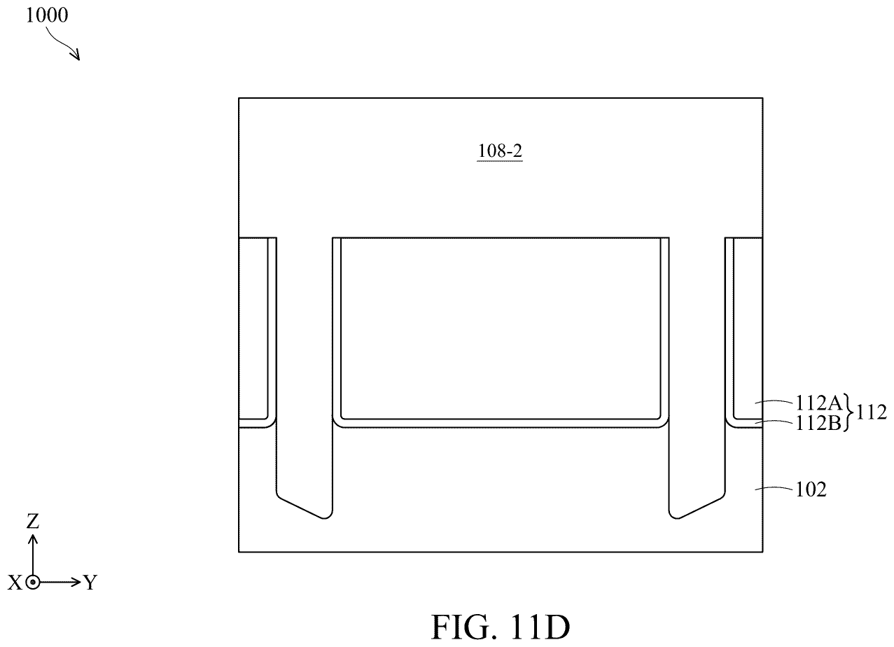

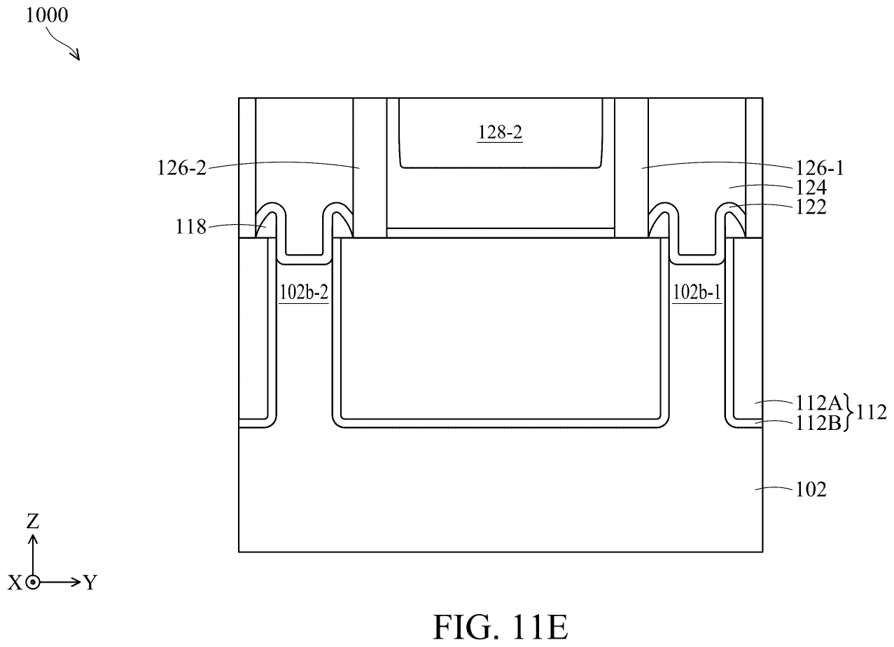

Referring to FIGS. 10A to 10E, the source/drain contacts 128-1 and 128-2 discussed above are formed in the CESL 122 and the ILD layer 124. More specifically, one or more lithography and etching processes may be performed to remove the portions of the CESL 122 and the ILD layer 124 in regions to be formed the source/drain contacts 128-1 and 128-2, and then the conductive material for the source/drain contacts 128-1 and 128-2 discussed above are formed in the regions to form the source/drain contacts 128-1 and 128-2. In some embodiments, the source/drain contacts 128-1 and 128-2 extend lengthwise in the Y-direction. The source/drain contacts 128-1 and 128-2 are formed between the dielectric structures 126-1 and 126-2 in the Y-direction, as shown in FIGS. 11A and 11E. Furthermore, the source/drain contacts 128-1 and 128-2 are formed on opposite sides of the dielectric structure 108-2 in the X-direction, as shown in FIGS. 11A and 11C. In some embodiments, the source/drain contact 128-1 is formed between the dielectric structures 108-1 and 108-2 in the X-direction, and the source/drain contact 128-2 is formed between the dielectric structures 108-2 and 108-3 in the X-direction, as shown in FIGS. 11A and 11C.

As discussed above, the source/drain contacts 128-1 and 128-2 are formed with other source/drain contacts over the source/drain features at the source/drain contact process stage. However, the source/drain contacts 128-1 and 128-2 are used for feed-through structure/cell and are not over and electrically connected to the source/drain features, as discussed above. Therefore, the source/drain contacts 128-1 and 128-2 may also be referred to as dummy source/drain contacts.

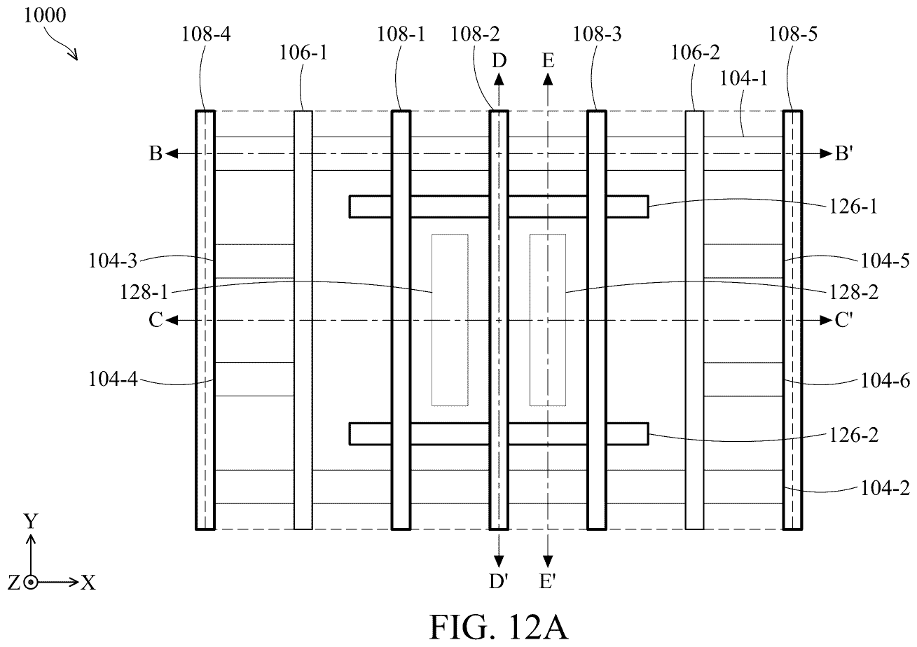

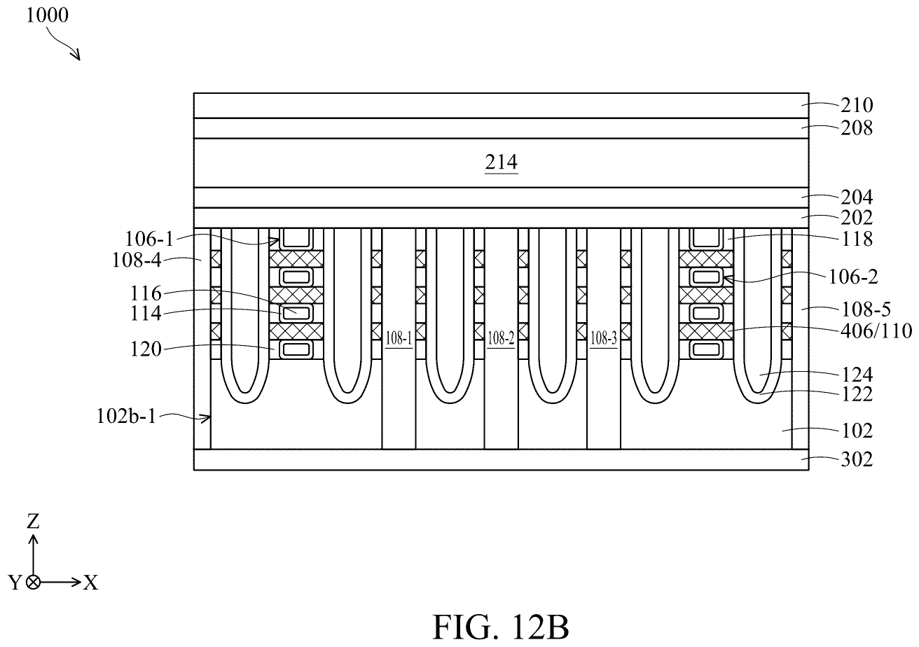

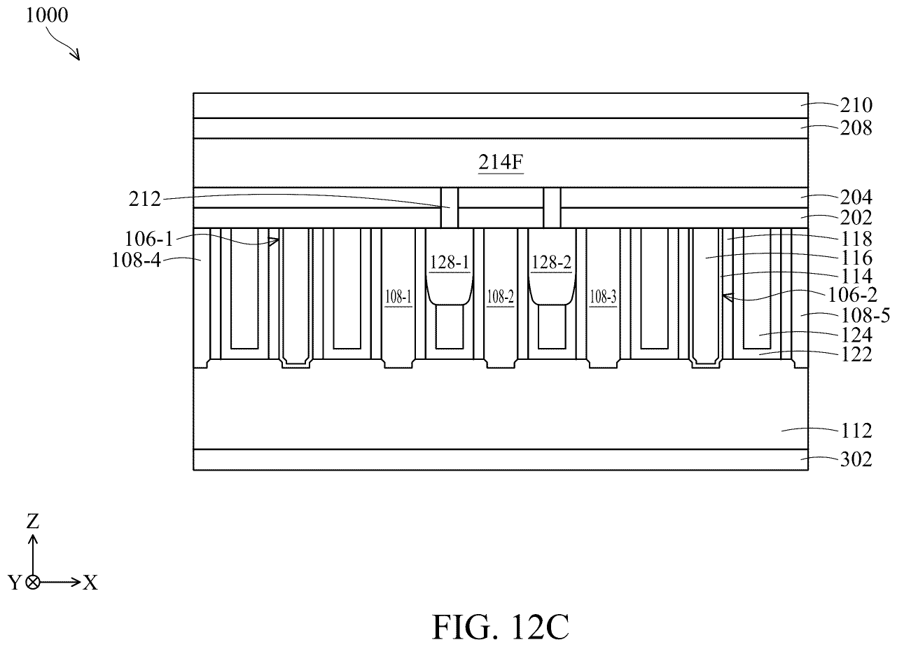

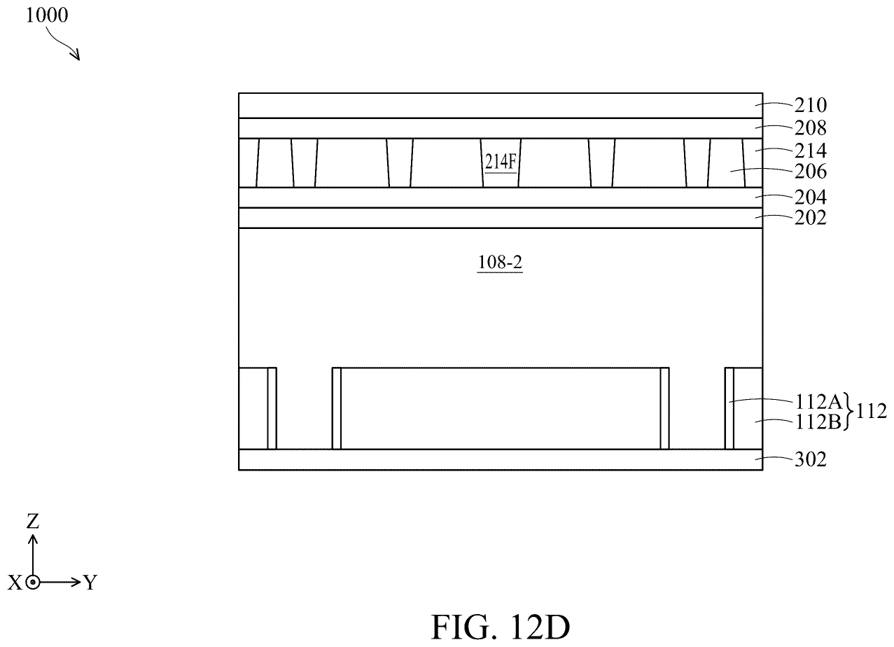

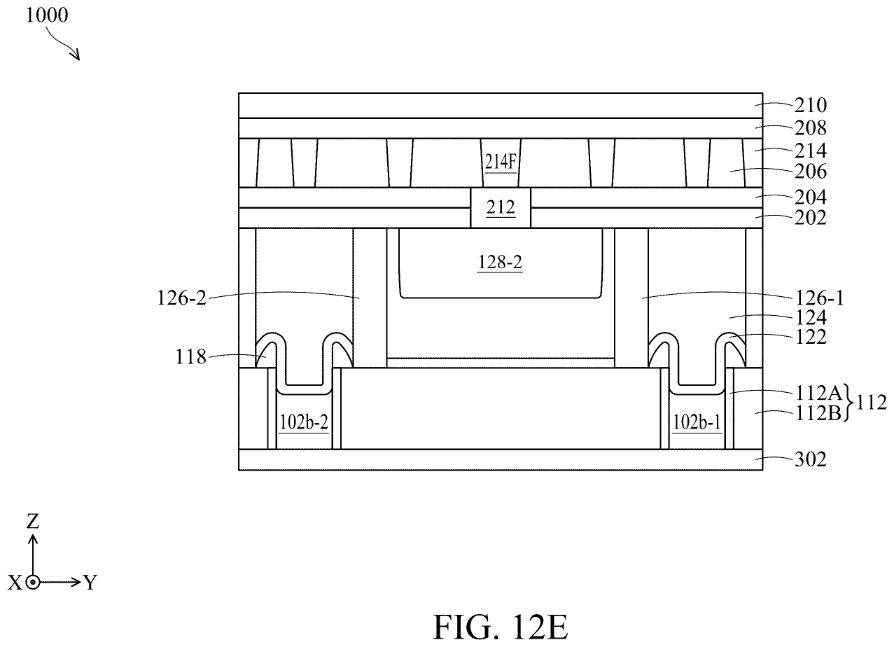

Referring to FIGS. 12A to 12E, the front-side interconnection structure including the CESL 202, the ILD layer 204, the ILD layer 206, the CESL 208, the ILD layer 210, the vias 212, the metal conductors 214, and the metal conductor 214F discussed above is formed over the gate structures 106, the dielectric structures 108, the source/drain contacts 128, the CESL 122, and the ILD layer 124. As shown in FIGS. 12A to 12E, the metal conductor 214F extends in the X-direction. The vias 212 are formed over and in contact with the source/drain contacts 128-1 and 128-2, and the metal conductor 214F is formed over and in contact with the vias 212. In some embodiments, the metal conductor 214F is electrically connected to the source/drain contacts 128-1 and 128-2 through the vias 212.

Still referring to FIGS. 12A to 12E, after the formation of the front-side interconnection structure, the workpiece 1000 may be flipped to form the feed-through via 130 and the back-side interconnection structure discussed above. For the purpose of simplicity, the sequent figures are shown without being flipped. As shown in FIGS. 12A to 12E, after the formation of the front-side interconnection structure, a CMP process and/or other planarization process is performed on a bottom surface of the workpiece 1000 to partially remove the substrate 102, the dielectric structures 108, and the isolation feature 112. After the CMP process, the dielectric layer 302 discussed above is formed under the substrate 102, the dielectric structures 108, and the isolation feature 112.

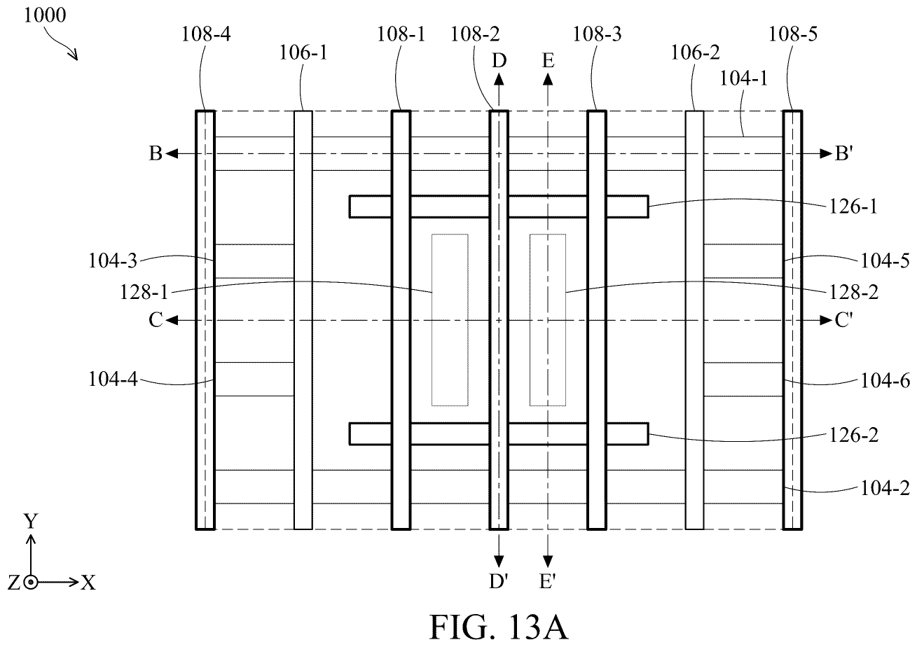

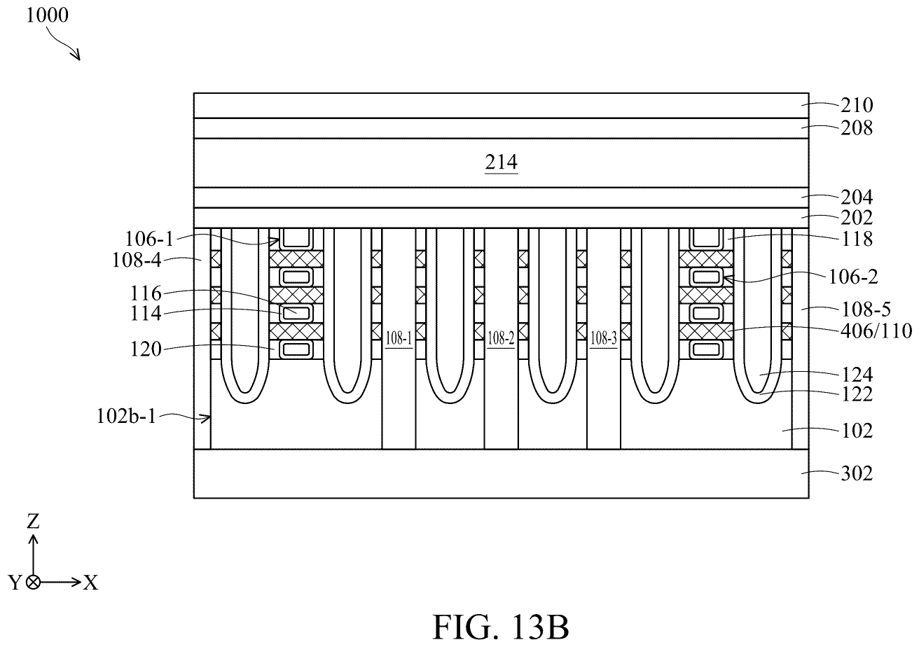

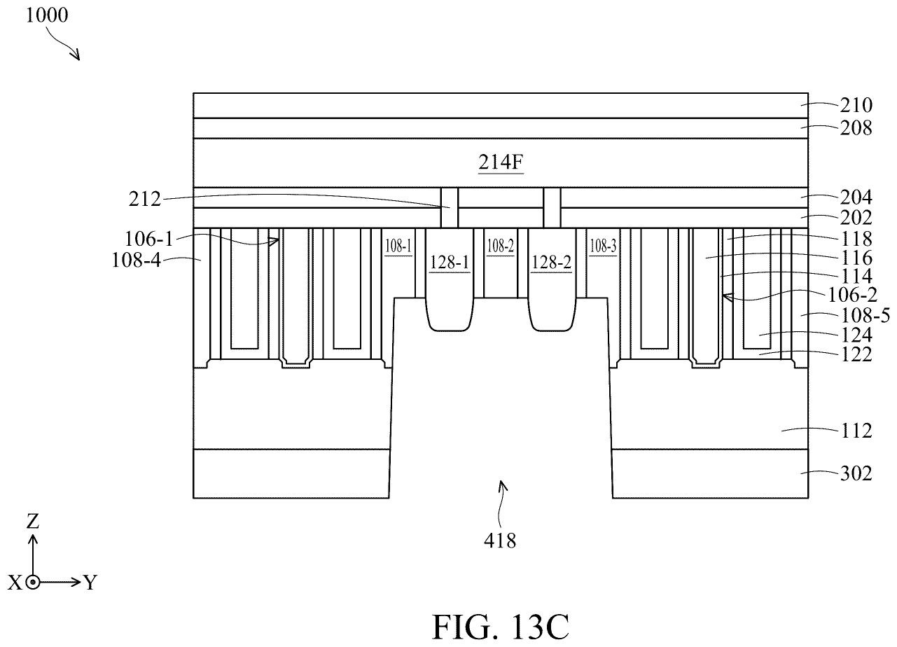

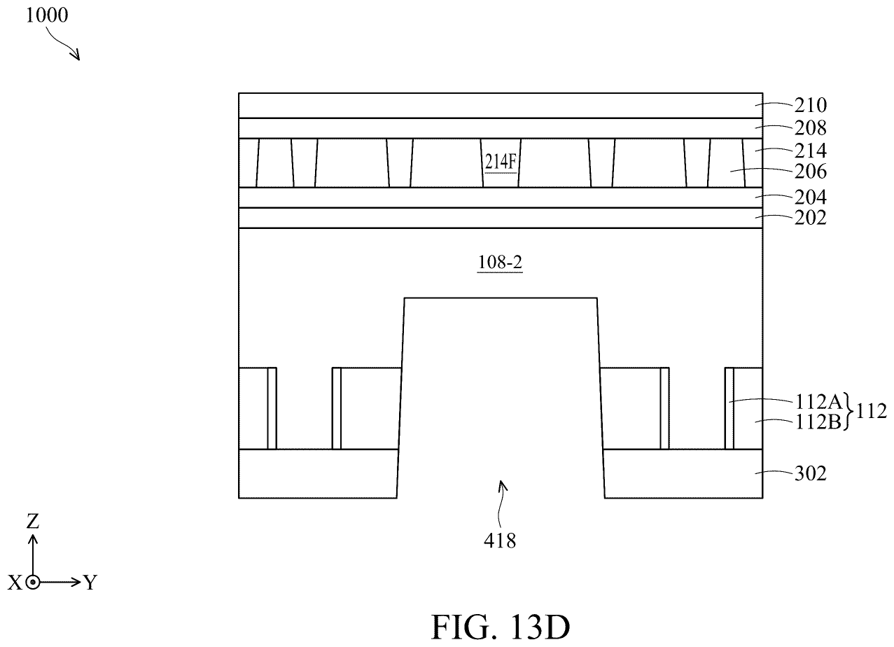

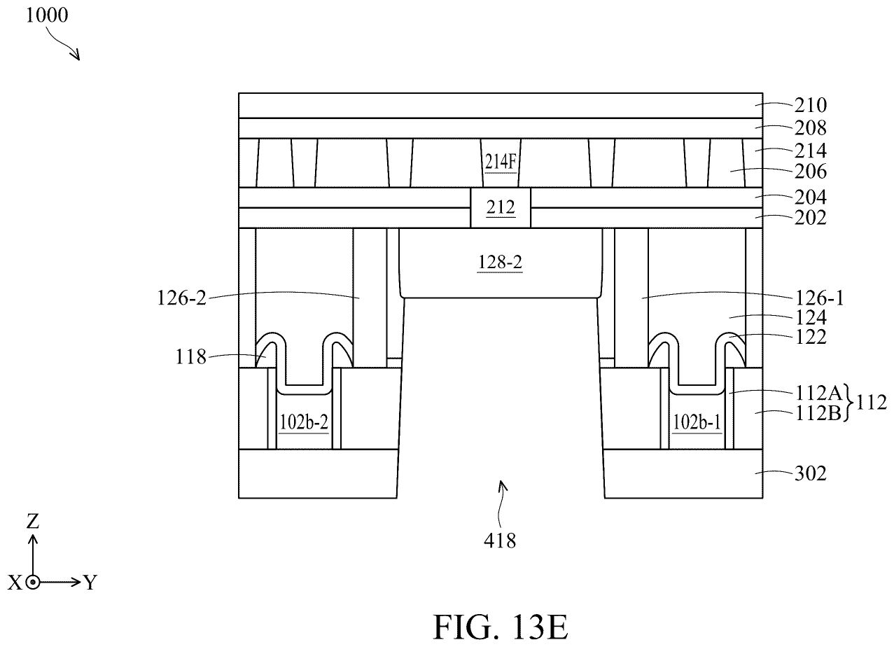

Referring to FIGS. 13A to 13E, an opening 418 is formed for the feed-through via 130 discussed above. More specifically, one or more lithography and etching processes may be performed to remove portions of the dielectric layer 302, the isolation feature 112, the dielectric structures 108, and the gate spacers 118, with minimal (or no) etching of the source/drain contacts 128-1 and 128-2 to form the opening 418. As shown in FIGS. 13C to 13E, the bottom surfaces and the sidewalls of the source/drain contacts 128-1 and 128-2 are exposed in the opening 418. Furthermore, the sidewalls of the dielectric structures 108, the isolation feature 112, the dielectric layer 302, the CESL 122, and the ILD layer 124 are exposed in the opening 418. It should be noted that, due to the dielectric structures 108-1 to 108-3 replacing the gate structures 106-4 to 106-6 (shown in FIGS. 9A to 9E) discussed above, the sidewalls of the source/drain contacts 128-1 and 128-2 are exposed without any gate structures slow down or impede the etching processes, which may cause the sidewalls of the source/drain contacts 128-1 and 128-2 to not be exposed.

Referring back to FIGS. 2A to 2E, after the formation of the opening 418, the feed-through via 130 discussed above is formed in the opening 418. More specifically, the adhesion layer 130A of the feed-through via 130 discussed above is first conformally formed in the opening 418, under the bottom surfaces of the isolation feature 112, the dielectric structures 108, the gate spacers 118, and the source/drain contacts 128, and on the sidewalls of the dielectric layer 302, the isolation feature 112, the CESL 122, the ILD layer 124, and the source/drain contacts 128. Then, the conductive layer 130B of the feed-through via 130 discussed above is formed in the opening 418 and on the adhesion layer 130A to fill the remaining space inside the adhesion layer 130A. As such, the feed-through via 130 including the adhesion layer 130A and the conductive layer 130B is formed under and in contact with the source/drain contacts 128-1 and 128-2 and the dielectric structures 108-1 to 108-3. As discussed above, the feed-through via 130 is also formed on and in contact with the sidewalls of the source/drain contacts 128, such that the contact area between the source/drain contacts 128 and the feed-through via 130 is increased to reduce the contact resistance between the source/drain contacts 128 and the feed-through via 130, thereby improving the performance of the semiconductor structure 100.

Still referring back to FIGS. 2A to 2E, after the formation of the feed-through via 130, the back-side interconnection structure including the ILD layer 304 and the metal conductor 306 discussed above is formed under the gate structures 106, the dielectric structures 108, the source/drain contacts 128, the CESL 122, the ILD layer 124, and the feed-through via 130. As shown in FIGS. 2A to 2E, the metal conductor 306 extends in the X-direction. The metal conductor 306 is formed under and in contact with the feed-through via 130. In some embodiments, the metal conductor 306 is electrically connected to the feed-through via 130.

As such, the workpiece 1000 with the semiconductor structure 100 including the feed-through structure/cell having the source/drain contacts 128-1 and 128-2 and the feed-through via 130 is provided. The feed-through structure/cell is used for electrical connection between a back-side metal line and a front-side metal line. As shown in FIGS. 2A to 2E, the feed-through structure/cell having the source/drain contacts 128-1 and 128-2 and the feed-through via 130 electrically connects the (front-side) metal conductor 214F to the (back-side) metal conductor 306. More specifically, the (front-side) metal conductor 214F is electrically connected to the (back-side) metal conductor 306 through the vias 212, the source/drain contacts 128-1 and 128-2, and the feed-through via 130, as shown in FIGS. 2A to 2E.

As discussed above, due to the gate structures 106-4 to 106-6 are replaced with the dielectric structures 108-1 to 108-3, the sidewalls of the source/drain contacts 128-1 and 128-2 are exposed without any gate structures slow down or impede the etching processes during the formation of the feed-through via 130. Therefore, the feed-through via 130 is in contact with the sidewalls of the source/drain contacts 128-1 and 128-2 to increase the contact area between the source/drain contacts 128 and the feed-through via 130, such that the contact resistance between the source/drain contacts 128 and the feed-through via 130 is reduced. As such, the feed-through structure/cell having the source/drain contacts 128-1 and 128-2 and the feed-through via 130 in the present embodiments has lower resistance, thereby reducing the IR drop and RC delay between the metal conductor 214F and the metal conductor 306, which electrically connected with each other by the feed-through structure/cell (having the source/drain contacts 128-1 and 128-2) and the vias 212.

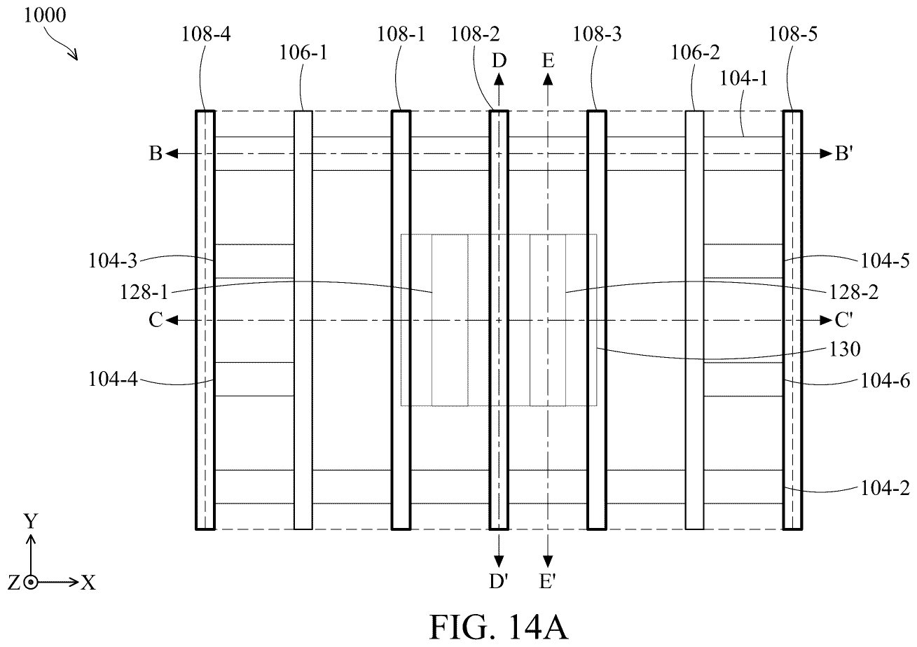

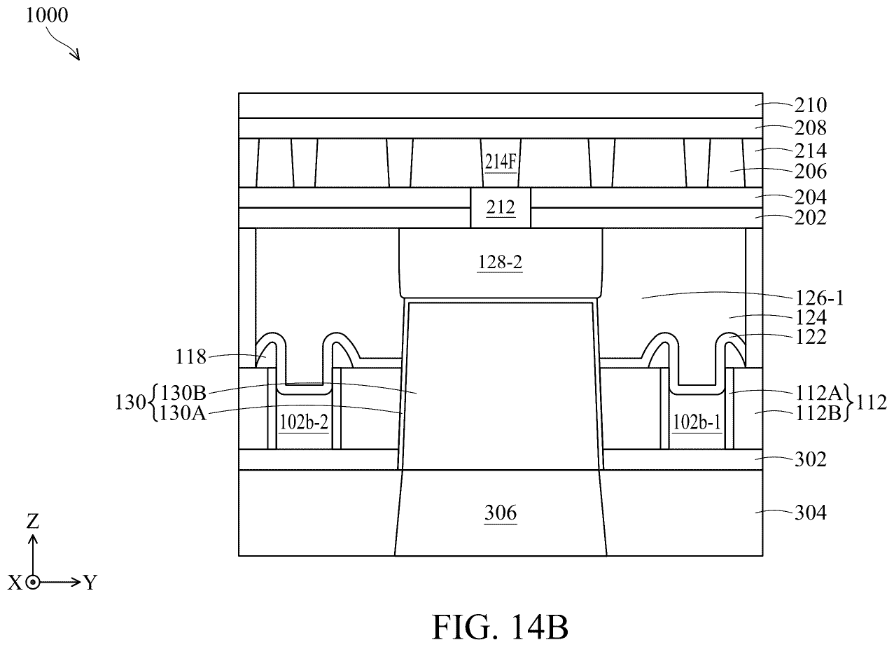

FIG. 14A illustrates a top view (or a layout) of a semiconductor structure 500 in the logic region 30 or memory region 20 of the IC chip 10, in accordance with some alternative embodiments of the present disclosure. FIG. 14B illustrates a Y-Z cross-sectional view of the semiconductor structure 500 along a line E-E′ of FIG. 14A, respectively, in accordance with some alternative embodiments of the present disclosure. The semiconductor structure 500 shown in FIGS. 14A and 14B is similar to the semiconductor structure 100 shown in FIGS. 2A to 2E, except that the dielectric structures 126-1 and 126-2 are omitted. As discussed above, the dielectric structures 126-1 and 126-2 are used for enhancing the isolation of the feed-through via 130 (specifically, the feed-through structure/cell) from other features. In the embodiments shown in FIGS. 14A and 14B, the dielectric structures 126-1 and 126-2 are omitted, such that the source/drain contacts 128-1 and 128-2 and the feed-through via 130 can have larger widths in the Y-direction, such that reducing the resistance of the feed-through structure/cell. In these embodiments, a distance between the feed-through via 130 and the dielectric structures 126-1 and 126-2 in the Y-direction is greater than or equal to 5.5 nm.

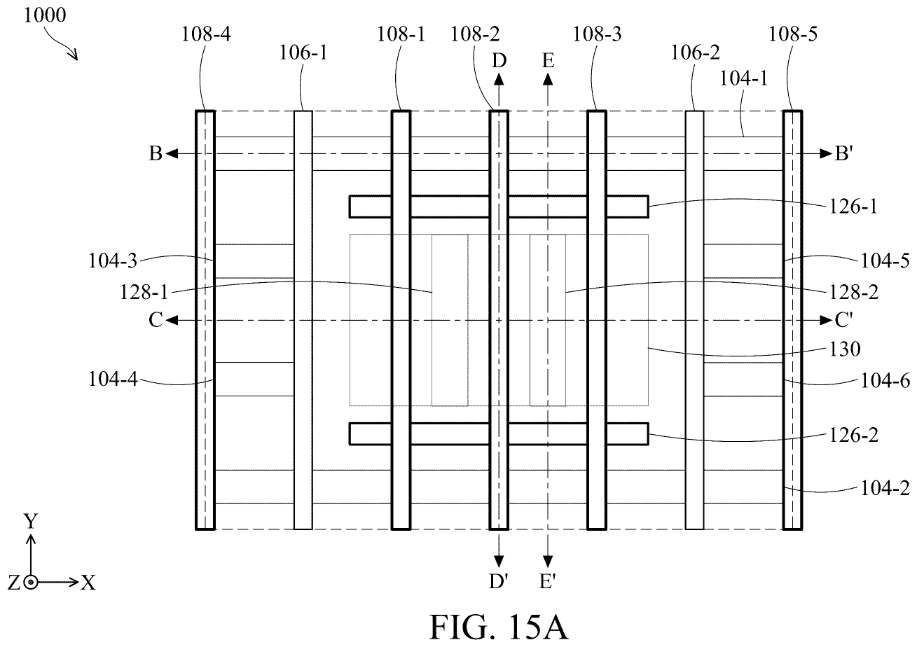

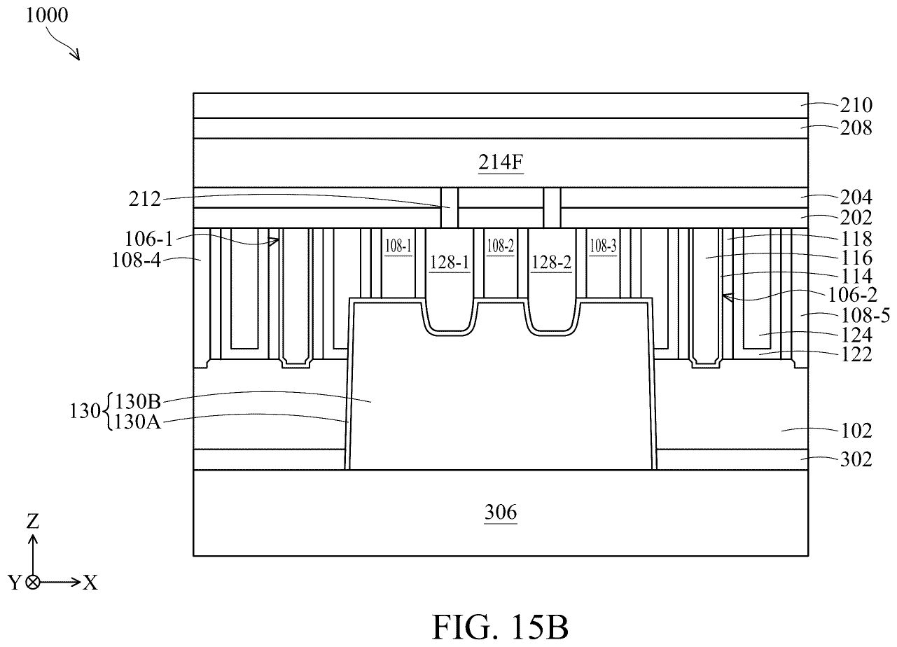

FIG. 15A illustrates a top view (or a layout) of a semiconductor structure 600 in the logic region 30 or memory region 20 of the IC chip 10, in accordance with some alternative embodiments of the present disclosure. FIG. 15B illustrates an X-Z cross-sectional view of the semiconductor structure 600 along a line B-B′ of FIG. 15A, respectively, in accordance with some alternative embodiments of the present disclosure. The semiconductor structure 600 shown in FIGS. 15A and 15B is similar to the semiconductor structure 100 shown in FIGS. 2A to 2E, except that the sidewalls of the feed-through via 130 is aligned with the sidewalls of the dielectric structures 126-1 and 126-2 in the Y-direction. Referring back to FIGS. 2A to 2E, as discussed above, the feed-through via 130 is in contact with sidewalls of the dielectric structures 108-1 and 108-3 in the X-direction. More specifically, as shown in FIG. 2A, the sidewalls of the feed-through via 130 is aligned with center lines of the dielectric structures 108-1 and 108-3 in the Y-direction, in accordance with some embodiments.

As shown in FIGS. 15A, the feed-through via 130 further extends in the X-direction, such that the sidewalls of the feed-through via 130 is aligned with the sidewalls of the dielectric structures 126-1 and 126-2 in the Y-direction. In some embodiments, the sidewalls of the feed-through via 130 is aligned with a center line between the gate structure 106-1 and the dielectric structure 108-1 in the Y-direction and a center line between the gate structure 106-2 and the dielectric structure 108-3 in the Y-direction. Furthermore, the sidewalls of the dielectric structures 126-1 and 126-2 is also aligned with the center line between the gate structure 106-1 and the dielectric structure 108-1 in the Y-direction and the center line between the gate structure 106-2 and the dielectric structure 108-3 in the Y-direction, as shown in FIG. 15A. As shown in FIGS. 15B, the feed-through via 130 is in contact with sidewalls of the CESL 122 and the ILD layer 124 in the X-direction.

The embodiments disclosed herein relate to semiconductor structures and their manufacturing methods, and more particularly to methods and semiconductor structures including a feed-through via structure that provides an electrical connection between a back-side metal conductor and a front-side metal line. Furthermore, the present embodiments provide one or more of the following advantages. The feed-through via in the feed-through via structure/cell is in contact with sidewalls of the source/drain contacts in the feed-through via, such that the contact area between the source/drain contacts and the feed-through via is increased to reduce the contact resistance between the source/drain contacts and the feed-through via, thereby improving the performance of the semiconductor structures.

Thus, one of the embodiments of the present disclosure describes a method for manufacturing a semiconductor structure that includes forming a first fin and a second fin extending in a first direction. Each of the first fin and the second fin includes first semiconductor layers and second semiconductor layers alternating stacked. The method further includes forming an isolation feature between the first fin and the second fin in a second direction perpendicular to the first direction, forming a dummy gate structure extending in the second direction and over the first fin, the second fin, and the isolation feature, forming an interlayer dielectric layer on opposite sides of the dummy gate structure in the first direction and over the isolation feature, replacing the dummy gate structure and the first semiconductor layers with a gate structure, replacing the gate structure with a first dielectric structure, forming source/drain contacts on opposite sides of the first dielectric structure in the first direction and over the isolation feature, and forming a feed-through via passing through the isolation feature and under and in contact with the source/drain contacts.

In another of the embodiments, discussed is a method for manufacturing a semiconductor structure including forming a first fin and a second fin extending in a first direction. Each of the first fin and the second fin includes first semiconductor layers and second semiconductor layers alternating stacked. The method further includes forming an isolation feature between the first fin and the second fin in a second direction perpendicular to the first direction, forming dummy gate structures extending in the second direction and over the first fin, the second fin, and the isolation feature, forming an interlayer dielectric layer between the dummy gate structures in the first direction and over the isolation feature, replacing the dummy gate structures and the first semiconductor layers with gate structures, replacing the gate structures with first dielectric structures over and in contact with the isolation feature, forming source/drain contacts in the interlayer dielectric layer and over the isolation feature, forming a first metal conductor over and electrically connected to the source/drain contacts, forming a feed-through via under and in contact with the source/drain contacts and the first dielectric structures, and forming a second metal conductor under and electrically connected to the feed-through via.

In yet another of the embodiments, discussed is a semiconductor structure including an isolation feature, dielectric structures, an interlayer dielectric layer, source/drain contacts, a feed-through via, a first metal conductor, and a second metal conductor. The semiconductor layers are over the substrate and spaced apart from each other in a Z-direction. The dielectric structures extend in a first direction and over the isolation feature. The interlayer dielectric layer is between the dielectric structures in a second direction perpendicular to the first direction. The source/drain contacts extend in the first direction and are in the interlayer dielectric layer. The feed-through via passes through the isolation feature and is under and in contact with the source/drain contacts and the dielectric structures. The first metal conductor extends in the second direction and is over and electrically connected to the source/drain contacts. The second metal conductor extends in the second direction and is under and electrically connected to the feed-through via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a first fin and a second fin extending in a first direction, wherein each of the first fin and the second fin comprises first semiconductor layers and second semiconductor layers alternating stacked;
forming an isolation feature between the first fin and the second fin in a second direction perpendicular to the first direction;
forming a dummy gate structure extending in the second direction and over the first fin, the second fin, and the isolation feature;
forming an interlayer dielectric layer on opposite sides of the dummy gate structure in the first direction and over the isolation feature;
replacing the dummy gate structure and the first semiconductor layers with a gate structure;
replacing the gate structure with a first dielectric structure;
forming source/drain contacts on opposite sides of the first dielectric structure in the first direction and over the isolation feature; and
forming a feed-through via passing through the isolation feature and under and in contact with the source/drain contacts.

2. The method of claim 1, further comprising:
forming vias over and in contact with the source/drain contacts; and
forming a metal conductor over and in contact with the vias, wherein a width of the vias in the second direction is greater than a width of the metal conductor in the second direction.

3. The method of claim 1, further comprising:
forming a metal conductor under and in contact with the feed-through via, wherein a width of the metal conductor in the second direction and a width of the feed-through via in the second direction are the same.

4. The method of claim 1, wherein the forming of the feed-through via further comprises:
recessing the isolation feature, the interlayer dielectric layer, and first dielectric structure to form an opening exposing bottom surfaces of the source/drain contacts;
forming an adhesion layer in the opening and on the bottom surfaces and sidewalls of the source/drain contacts; and
forming a conductive layer in the opening and on the adhesion layer.

5. The method of claim 1, further comprising:
forming second dielectric structures in the interlayer dielectric layer and extending in the first direction; and
forming the source/drain contacts between the second dielectric structures in the second direction.

6. The method of claim 5, wherein a distance between the feed-through via and the second dielectric structures in the second direction is greater than 5.5 nm.

7. The method of claim 5, wherein sidewalls of the feed-through via are aligned with sidewalls of the source/drain contacts.

8. The method of claim 1, wherein the feed-through via is in contact with sidewalls of the source/drain contacts.

9. The method of claim 1, wherein a distance between a topmost surface of the feed-through via and bottom surfaces of the source/drain contacts is in a range from about 15 nm to about 25 nm.

10. The method of claim 1, further comprising:
a contact etch stop layer on sidewalls of the second semiconductor layers, wherein the interlayer dielectric layer is over the contact etch stop layer.

11. A method for manufacturing a semiconductor structure, comprising:
forming a first fin and a second fin extending in a first direction, wherein each of the first fin and the second fin comprises first semiconductor layers and second semiconductor layers alternating stacked;
forming an isolation feature between the first fin and the second fin in a second direction perpendicular to the first direction;
forming dummy gate structures extending in the second direction and over the first fin, the second fin, and the isolation feature;
forming an interlayer dielectric layer between the dummy gate structures in the first direction and over the isolation feature;
replacing the dummy gate structures and the first semiconductor layers with gate structures;
replacing the gate structures with first dielectric structures over and in contact with the isolation feature;
forming source/drain contacts in the interlayer dielectric layer and over the isolation feature;
forming a first metal conductor over and electrically connected to the source/drain contacts;
forming a feed-through via under and in contact with the source/drain contacts and the first dielectric structures; and
forming a second metal conductor under and electrically connected to the feed-through via.

12. The method of claim 11, further comprising:
forming an opening exposing bottom surfaces and sidewalls of the source/drain contacts; and
forming the feed-through via in the opening.

13. The method of claim 11, wherein a topmost surface of the feed-through via is higher than bottom surfaces of the source/drain contacts.

14. The method of claim 13, wherein the topmost surface of the feed-through via is level with a half of a dimension of sidewalls of the source/drain contacts.

15. The method of claim 11, further comprising:
forming second dielectric structures in the interlayer dielectric layer and extending in the first direction; and
forming the feed-through via between the second dielectric structures in the second direction.

16. The method of claim 11, wherein the feed-through via is in contact with the first dielectric structures in the first direction.

17. The method of claim 11, wherein a width of the source/drain contacts in the second direction and a width of the feed-through via in the second direction are the same.

18. A semiconductor structure, comprising:
an isolation feature;
dielectric structures extending in a first direction and over the isolation feature;
an interlayer dielectric layer between the dielectric structures in a second direction perpendicular to the first direction;
source/drain contacts extending in the first direction and in the interlayer dielectric layer;
a feed-through via passing through the isolation feature and under and in contact with the source/drain contacts and the dielectric structures;
a first metal conductor extending in the second direction and over and electrically connected to the source/drain contacts; and
a second metal conductor extending in the second direction and under and electrically connected to the feed-through via.

19. The semiconductor structure of claim 18, further comprising:
gate structures on opposite sides of the dielectric structures in the second direction, wherein sidewalls of the feed-through via are separated from the gate structures in the second direction.

20. The semiconductor structure of claim 19, wherein a distance between the sidewalls of the feed-through via and the gate structures in the second direction is in a range from about 20.2 nm to about 45 nm.
